(19) United States
(12) Patent Application Publication
(10) Pub. No.: US 2025/0200261 A1
(43) Pub. Date: Jun. 19, 2025

(54) INTEGRATED DIGITAL CIRCUIT AND METHOD OF RECONFIGURING THE SAME

(71) Applicant: 5G3I Ltd, London (GB)

(72) Inventor: Taner DOSLUOGLU, Glasgow (GB)

(73) Assignee: 5G3I Ltd, London (GB)

(21) Appl. No.: 18/847,633

(22) PCT Filed: Mar. 21, 2023
(86) PCT No.: PCT/GB2023/050709

§ 371 Date: Sep. 16, 2024

Related U.S. Application Data
(60) Provisional application No. 63/329,570, filed on Apr. 11, 2022.

(51) Int. Cl. G06F 30/34; G06F 30/27; G06F 30/327

(52) U.S. Cl. CPC G06F 30/34; G06F 30/27; G06F 30/327

(57) ABSTRACT

A reconfigurable integrated circuit is presented. The reconfigurable integrated circuit (300) includes a plurality of active cells (302); and an adaptive neural network cell (304) coupled to one or more active cells. The adaptive neural network cell (304) has a digital neural network circuit (306) implementing a first neural network (308) having a plurality of weights and biases. For specific weights and biases and specific neural network inputs, the first neural network (308) provides specific neural network outputs. The adaptive neural network cell (304) is configurable with a set of target weights to achieve a target circuit modification.

The present disclosure relates to reconfigurable integrated circuits and method of reconfiguring an integrated system. In particular, the present disclosure relates to reconfigurable integrated circuits comprising an adaptive neural network cell.

### BACKGROUND

Engineering change order (ECO) is a crucial element in the design of very large scale integrated (VLSI) circuits. ECO can be used to implement small-scale changes in the circuit design, typically in the late stage of the design process. The changes may concern functional or non-functional aspects of the circuit, such as positioning of the components, timing, dissipation, etc. Often, ECO changes are necessary to fix design defects and/or to meet modified circuit constraints.

Because of the complexity and high costs involved in applying changes to a VLSI circuit, it is common practice to include spare (unused) library cells in the circuit design. These are usually placed in areas of low component density. Such spare cells are embedded in the design but are not active, for instance they are not driving any other components of the circuit. The idea is that if needed they can be used to enable a relatively easy fix at any stage of the design process without the need of a full redesign. The use of spare cell allows to fix and/or change the functional or non-functional aspects of a circuit even in the post-silicon or tape out phase with relatively limited modifications. If the appropriate spare cells are present, a simple re-routing is sufficient to satisfy an ECO requirement, which means only the metal masks, that is the connections masks, need to be changed.

Spare cells may include custom combinational logic cells, such as inverters, buffers, NAND, OR, NOR, AND, AOI, OAI gates, multiplexers (MUX) and demultiplexer (DEMUX) cells; sequential logic cells, such as flip-flops, scan flip-flops, D-type transparent latches, and/or support cells, such as filler cells with and without decoupling capacitors. Spare cell libraries are provided in most computer aided circuit design tools.

Following a re-design in response to an ECO, spare cells may become active cells to substitute one or more original committed, or active, cells; and an active cell may be re-committed or become a new spare cell.

For example, a circuit designer may realize during the testing phase that a logic AND cell needs to be replaced by a NAND cell. If a spare NAND cell is available in the original circuit design, it is then sufficient to re-design the metal connection masks to re-route the signal to the correct cells and replace the AND cell with the spare NAND cell.

Typically, a metal fix, that is a re-design of the metal mask(s), will be required in order for a spare cell to become an active component of the circuit; that is, new connections will need to be made between one or more of the functional components of the original design and one or more of the spare library cells.

Another scenario in which spare cells may come to the rescue is when timing problems emerge late in the circuit design process. Similarly, ECO may be performed to address power problems, dissipation problems, layout problems and so on.

Whether functionality (logic or non-logic), timing, layout or other issues are in question, if an appropriate set of spare cells has been included in the original circuit design, it is possible to rectify the erroneous or defective design at the post-layout or even post-silicon stage with a re-routing in the cheaper, metal layer masks, without having to change the base layer process masks, which would result in much higher costs and time delays in the production cycle.

Spare cells have proven especially important for mixed signal (analog/digital) circuits, which often have limited digital design resources in terms of engineering tools, physical space available on silicon, power and timing constraints, time to tape-out. Very often, mixed signal circuits require system level changes late in the design phase or post silicon release and these can in most cases be resolved with easy metal mask fixed thanks to the use of spare cells.

ECO methods are an active fields of research and have been widely discussed in literature, for example by Huang et al. in “A robust ECO engine by resource-constraint-aware technology mapping and incremental routing optimization,”, 2011, pp. 382-387 (doi: 10.1109/ASPDAC.2011.5722218); (https://doi.org/10.3390/electronics8060661) by Jiang et al. in “Engineering Change Order for Combinational and Sequential Design Rectification,” 2020 (doi: 10.23919/DATE48585.2020.9116504); by Chen et al. in “ECO Timing Optimization Using Spare Cells and Technology Remapping,” (doi: 10.1109/TCAD.2010.2043573); and by Wei et al. in “ECO timing optimization with negotiation-based re-routing and logic re-structuring using spare cells,” (doi: 10.1109/ASPDAC.2012.6165006).

Although many commercial and non-commercial ECO solutions providing spare cells for VLSI design are available, there remains much room for improvement.

Prior art ECO-capable circuits and prior art integrated circuit design methods are still limited in that they require new routing mask layers to be produced when an issue is identified late in the design process (after the metal masks has been produced).

Moreover, they are limited in that only a restricted number of cells are currently used as spare cells, hence limiting the number of corrections that can be achieved in response to an ECO. If the logic cells required to implement the required IC change are not available among the spare cells in the IC design, then the whole integrated circuit mask must be replaced.

It would be desirable to provide a system which allows to apply corrections in the design of integrated circuits at any stage of the design process, including after tape out and/or in the late debugging and validation stages, without requiring any metal layer or any other types of changes in the physical masks. It would also be desirable to provide a system which enables an increased number of corrections and/or changes in response to an ECO.

### SUMMARY

According to a first aspect of the disclosure there is provided a reconfigurable integrated circuit comprising: a plurality of active cells; and an adaptive neural network cell (704) coupled to one or more active cells (710, 712, 714), the adaptive neural network cell comprising a digital neural network circuit (706) configured to implement a first neural network (708) having a plurality of weights and biases, wherein for specific weights and biases and specific neural network inputs, the first neural network provides specific neural network outputs; wherein the adaptive neural network cell (704) is configurable with a set of target weights to achieve a target circuit modification.

Optionally, the adaptive neural network cell (704) has an active state and a passive state, wherein in the active state the adaptive neural network cell (704) provides target outputs for the target circuit modification.

Optionally, in the passive state the outputs of the adaptive neural network cell (704) are all set to a logic zero or all set to a predefined set of outputs that do not achieve the target circuit modification.

Optionally, the first neural network has one or more hidden nodes and wherein the digital neural network circuit comprises a first circuit portion (902A, 902B) to provide a plurality of hidden node values and a second circuit portion (904) to provide one or more output values.

Optionally, the first circuit portion (902A, 902B) comprises: a first set (906) of stage 1 circuits (908) associated with a corresponding input signal and a corresponding hidden node, wherein each stage 1 circuit (908) is adapted to receive the corresponding input signal (I1) and one or more weight signals (w_a11, w_b11) encoding the weight of the corresponding input signal and the corresponding hidden node; and provide one or more output signals (G11 M11) associated with a product function for determining the corresponding hidden node (eq 1); and a second set (910A, 910B) of stage 2 circuits wherein each stage 2 circuit (912) is associated with a corresponding hidden node, wherein each stage-2 circuit is adapted to receive one or more outputs signals from each stage 1 circuit associated with the corresponding hidden node and to provide a value of the corresponding hidden node.

Optionally, the second circuit portion (904) is analogous to the first portion.

Optionally, the first neural network is a deterministic neural network.

Optionally, one or more of the inputs, the outputs, the weights of the first neural network are quantized.

Optionally, one or more of the outputs, the inputs, the weights of the first neural network are binarized.

Optionally, the plurality of active cells comprises one or more active logic cells.

Optionally, the plurality of active cells comprises at least one of: a combinatorial logic cell and a sequential logic cell.

Optionally, the adaptive neural network cell is configurable to implement a logic cell.

Optionally, one of the active cells comprises a digital circuit implementing a second neural network and the first neural network is an extension of the second neural network.

Optionally, the adaptive neural network cell is further configurable with a set of target biases to achieve the target circuit modification.

According to a second aspect of the disclosure there is provided a method of reconfiguring an integrated circuit, the method comprising: providing an integrated circuit comprising a plurality of active cells and an adaptive neural network cell coupled to one or more active cells, the adaptive neural network cell comprising a digital neural network circuit configured to implement a first neural network having a plurality of weights and biases; wherein for specific weights and biases and specific neural network inputs, the first neural network provides specific neural network outputs; identifying a target circuit modification to be achieved via the adaptive neural network cell; determining a set of weights associated with target outputs for the target circuit modification; configuring the adaptive neural network cell with the set of weights to achieve the target circuit modification.

Optionally, the adaptive neural network cell has an active state and a passive state, wherein in the active state the adaptive neural network cell provides target outputs for the target circuit modification; and the method further comprises: prior to a target circuit modification being identified, setting all the neural network outputs to zero to achieve the passive state; OR determining a set of weights associated with the passive state and configuring the adaptive neural network cell with the set of weights to achieve the passive state.

Optionally, determining the set of weights to achieve the target circuit modification comprises training the first neural network via a processor.

Optionally, the plurality of active cells comprises an inverter between a first logic block and a second logic block, and the method further comprises: replacing the inverter with an XNOR gate or AOI gate; and coupling the adaptive neural network cell between the first logic block and the XNOR gate or the AOI gate.

Optionally, the method further comprises: determining a set of biases associated with target outputs for the target circuit modification; and configuring the adaptive neural network cell with the set of biases to achieve the target circuit modification.

The method of the second aspect may also incorporate using or providing features of the first aspect and various other steps as disclosed herein.

### BRIEF DESCRIPTION OF THE DRAWINGS

The disclosure is described in further detail below by way of example and with reference to the accompanying drawings in which:

FIG. 1 is a schematic diagram of a method of reconfiguring an integrated circuit according to the prior art;

FIG. 2A is a schematic diagram of an integrated circuit comprising a spare logic cell according to the prior art;

FIG. 2B is a schematic diagram of the integrated circuit of FIG. 2A after the circuit has been modified in response to an ECO;

FIG. 3 is a schematic diagram of a reconfigurable integrated circuit according to a first aspect of the present disclosure;

FIG. 4 is a schematic diagram of a method of reconfiguring an integrated circuit according to a second aspect of the present disclosure;

FIG. 5 is a schematic diagram of a method of reconfiguring an integrated circuit, according to a first embodiment of the method of FIG. 4;

FIG. 6 is a schematic diagram of a configurable integrated circuit according to the prior art;

FIG. 7 is a schematic diagram of an integrated circuit according to a first embodiment of the circuit of FIG. 3, the circuit comprising a digital neural network circuit for implementing a neural network;

FIG. 8 is a schematic diagram of a neural network topology according to a specific embodiment of the neural network of FIG. 7;

FIG. 9A is a schematic diagram of a digital neural network circuit according to a specific embodiment of the digital neural network circuit of FIG. 7 having biases=−1.5;

FIG. 9B is a schematic diagram of a digital neural network circuit according to a further specific embodiment of the digital neural network circuit of FIG. 7 having biases=−0.5;

FIG. 9C is a schematic diagram of a portion of the digital neural network circuit of FIG. 7 according to a further specific embodiment of the digital neural network circuit of FIG. 7;

FIG. 10 is a further schematic diagram of a digital neural network circuit according to an embodiment of the digital neural network circuit of FIG. 7;

FIG. 11 is a schematic diagram of an integrated circuit according to a second embodiment of the circuit of FIG. 3;

FIG. 12 is a schematic diagram of an integrated circuit according to a third embodiment of the circuit of FIG. 3;

FIG. 13 is a schematic diagram of an integrated circuit according to a fourth embodiment of the circuit of FIG. 3;

FIG. 14 is a schematic diagram of a digital neural network circuit according to a specific embodiment of the digital neural network circuit of FIG. 13;

FIG. 15A is a schematic diagram of a circuit portion prior to the insertion of an adaptive neural network cell;

FIG. 15B is a schematic diagram of the circuit portion of FIG. 15A following the insertion of an adaptive neural network cell;

FIG. 16 is a schematic diagram of a configurable integrated circuit according to a fifth embodiment of the circuit of FIG. 3;

FIG. 17 is a graph illustrating a simulation of the signals of the circuit of FIG. 16 prior to implementing deglitching;

FIG. 18 is a graph illustrating a simulation of the signals of the circuit of FIG. 16 after configuring the adaptive neural network cell to implement deglitching;

FIG. 19A is a schematic diagram of a neural network topology;

FIG. 19B is a schematic diagram of the neural network topology of FIG. 19A modified to include redundant nodes;

FIG. 20 is a schematic diagram of a configurable integrated circuit according to a sixth embodiment of the circuit of FIG. 3;

FIG. 21 is a schematic diagram of a configurable integrated circuit according to a seventh embodiment of the circuit of FIG. 3;

FIG. 22 is a schematic diagram of a prior art digital circuit for use in a mixed-signal (analog/digital) circuit;

FIG. 23 is a schematic diagram of a prior art digital circuit which is configured to provide timing critical signals for controlling the analog portion of a mixed-signal circuit; and

FIG. 24 is a schematic diagram of a digital circuit which combines deterministic neural networks with combinational and sequential logic blocks according to a third aspect of the present disclosure.

### DETAILED DESCRIPTION

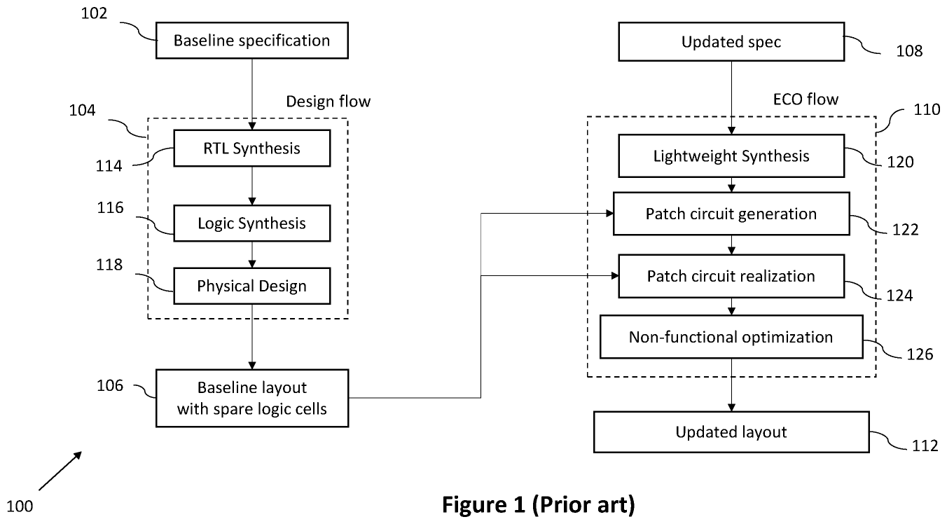

FIG. 1 is a schematic diagram of a method 100 of reconfiguring an integrated circuit according to the prior art.

The method 100 comprises step for adjusting a baseline layout of an integrated circuit design in response to an engineering change order, where the baseline layout is the initial, or original, design of the circuit, comprising a description of each component and its connectivity. The baseline layout may be given for example in the form of a netlist.

The method 100 is not meant to perfectly match all the details of industrial practice, but to highlight the essential steps throughout the overall ECO process.

The method 100 comprises: at step 102, providing a specification file for the original circuit design; at step 104, synthetizing the circuit; at step 106, generating a baseline circuit layout which comprises one or more (inactive) spare logic cells; at step 108, upon an error being found or the specification being changed, providing an updated specification file; at step 110, rectifying the original layout in response to the ECO; at step 112, generating an updated layout file with minimal modifications to the baseline files to be used for the IC fabrication.

Step 106 generally comprises various synthesis stages. For example, step 106 may comprise: a register transfer level (RTL) synthesis step 114, a logic synthesis step 116; and a physical design step 118. The physical design comprises spare cells, which are unused, or inactive, standard cells uniformly distributed across the design. Spare cells may be automatically selected and placed in the circuit layout from pre-determined libraries available in circuit design software tools or manually selected and placed in the layout by the circuit designer.

Step 110 also generally comprises multiple rectification steps. For example, step 110 may comprise: at step 120, receiving in input the baseline layout file and the updated specification and running a lightweight synthesis on the latter to generate a logic gate netlist of the updated design; at step 122, generating a patch circuit, which aims at extracting the logical difference between the original and the updated designs by generating a subcircuit for design rectification; at step 124, realizing the patch circuit by integrating the patch circuit into the original layout; at step 126, optimizing the layout for non-functional design concerns, such as to resolve potential timing violations or IR drops caused by the realization of the patch circuit.

Depending on the types of specification changes, design errors, and the applied synthesis techniques in the design flow, the updated logic gate netlist generated at step 120 may or may not have one-to-one register correspondence to the original netlist.

Thanks to the presence of spare cells in the baseline layout, if an error is found or the specification gets changed at a late stage of the design flow, instead of having to repeat the entire designs flow (step 102 through 106), the ECO flow (steps 108 to 112) allows to update the baseline IC layout with minimal disturbance, so as to maximally reuse the previously invested optimization efforts.

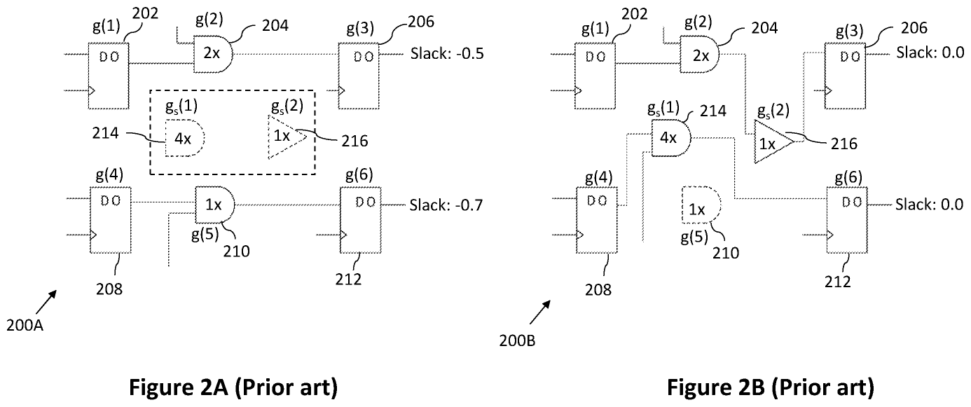

Spare cells are often used to optimize circuit timing. For example, engineers may realize that a given functional change causes timing violations. An example is illustrated in FIGS. 2A and 2B.

FIG. 2A is a schematic diagram of an integrated circuit 200 comprising a spare cell. The circuit 200 comprises a plurality of active cells 202 through to 212 and two spare cells 214 and 216. In this specific example, spare cell 214 is an AND gate gS(1) and the spare cell 216 is a buffer gate gS(2). Gates g(1) (202), g(3) (206), g(4) (208), and g(6) (212) are D-type flip-flops. Gates g(2) (204) and g(5) (210) are AND gates.

The spare cells 214 and 216 are initially not connected to any path. Cells 202, 204 and 206 form a first path and cells 208, 210 and 212 form a second path. Supposing that the delays of the first path and second path violate the timing constraints of the IC, then a fix would be required.

FIG. 2B is a schematic diagram of the integrated circuit 200 after the circuit has been modified in response to an ECO to fix the timing violations of FIG. 2A. The buffer gS(2) (spare cell 216) is inserted into the first path to help drive the load and fix the timing of the first path. The AND gate gS(1) (spare cell 214) is inserted into the second path instead of the AND gate g(5) (210) because gS(1) has a larger driving capability and can fix the timing violation of path 2. In the re-wired circuit of FIG. 2B both paths satisfy the timing constraints. The logic gate g(5) (210) has been released from the netlist and has become a spare cell.

The above systems and methods are limited in that in order to re-use the space cell it would always be necessary to perform some re-routing to adjust the connections within the IC design.

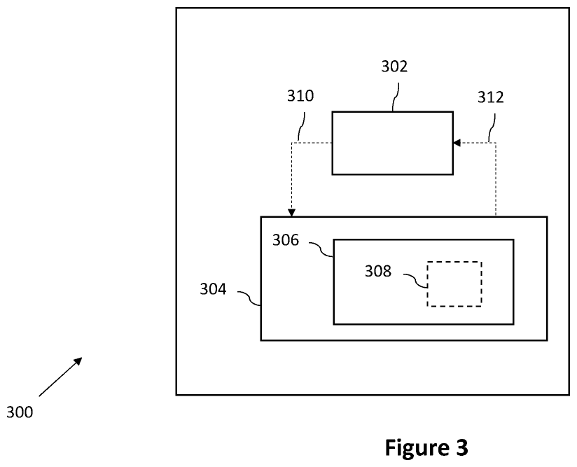

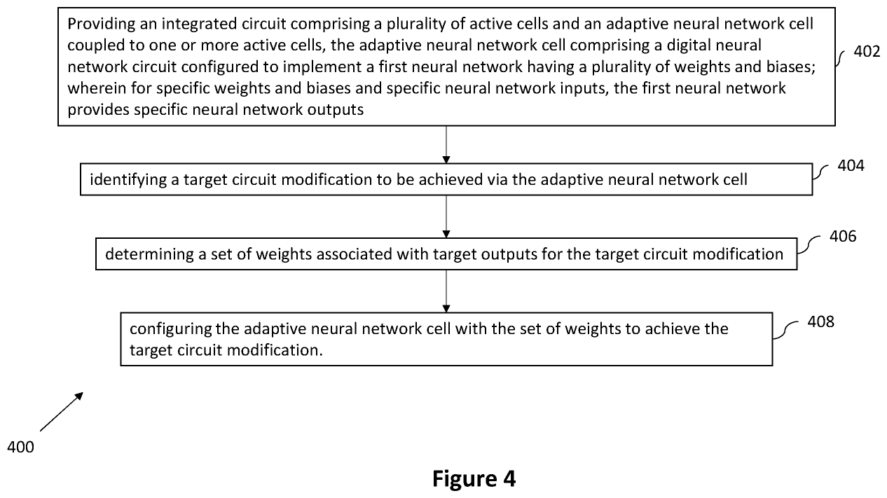

FIG. 3 is a schematic diagram of a reconfigurable integrated circuit 300 according to a first aspect of the present disclosure. The reconfigurable integrated circuit 300 comprises a plurality of active cells 302 and an adaptive neural network (NN) cell 304. The adaptive neural network cell 304 has one or more inputs 310 and one or more outputs 312, where the inputs 310 and the output 312 are coupled to the one or more active cells 302. The adaptive NN cell 304 comprises a digital neural network circuit 306, configured to implement a neural network 308 having a plurality of weights and biases. For specific weights and biases and for specific neural network inputs, the neural network 308 provides specific neural network outputs.

It will be appreciated that in some embodiments, the adaptive NN cell 304 only comprise the digital neural network circuit 306 and the inputs 310 (outputs 312) of the adaptive NN cell 304 are the inputs (outputs) of the digital NN circuit 306. However, there may also be embodiments in which the adaptive NN cell 304 comprises additional components coupled before or after the digital NN circuit 306.

Either way, the digital NN circuit 306 can be configured with a set of target weights such that for a specific set of target weights values and specific biases, inputs provided to the digital neural network circuit 306 provides specific outputs 310. By configuring the digital NN circuit 306 with a set of target weights and by providing the output 310 to the plurality of active cell 302, the overall functionality of integrated circuit 300 can be modified as required by an ECO.

The adaptive neural network cell 304 may also be referred to in the following as “spare neural network cell”, and the digital NN circuit 306 may also be referred to as a “spare NN circuit” or “spare digital NN circuit”.

The adaptive neural network cell 304 is configurable with a set of target weights to achieve a target circuit modification. For example, the adaptive neural network cell 304 may be configurable to change, or adjust, the workings of the plurality of active cells 302 in response to an engineering change order.

In the present disclosure “active cells” refers to “committed cells”, that is, cells which are committed to a specific functionality according to the circuit design. In contrast, “spare” means a circuit portion, cells or component which is not committed to a specific functionality in the original circuit layout, or design.

Active cells may comprise individual electronic components or groups of components. For example, active cells may comprise logic gates, or blocks of logic gates.

In particular, active cells may comprise logic active cells, such as combinatorial or sequential logic active cells, or a combination of the two.

The configurable integrated circuits and IC layouts or design according to the present disclosure may also be referred to as Engineering Change Order (ECO)-capable integrated circuit, or simply ECO-IC.

FIG. 4 is a schematic diagram of a method 400 of reconfiguring an integrated circuit, according to a second aspect of the present disclosure. The method 400 comprises: at step 402, providing an integrated circuit comprising a plurality of active cells and an adaptive neural network cell coupled to one or more active cells, the adaptive neural network cell comprising a digital neural network circuit configured to implement a first neural network having a plurality of weights and biases; wherein for specific weights and biases and for specific neural network inputs the first neural network provides specific neural network outputs; at step 404, identifying a target circuit modification to be achieved via the adaptive neural network cell; at step 406, determining a set of weights associated with target outputs for the target circuit modification; and at step 408, configuring the adaptive neural network cell with the set of weights to achieve the target circuit modification.

The circuit modification may be for example a change required by an ECO. Although the word ECO is often associated with industry-specific tools, in the present disclosure ECO is used in a general way to refer to any adjustment which may become necessary following an error or a specification change after a first version of an integrated circuit design is produced, whether via automated or non-automated tools.

It will be appreciated that an ECO might be implemented in the form of a computer-readable file to take advantage of modern IC design tools, however in the present disclosure ECO may refer to change orders expressed in any format and medium, including verbal communication.

Circuit modifications, adjustments or corrections may refer to any aspect which can affect the layout and/or the workings of an active cells or group of active cells within the integrated circuit, such as functional aspects, timing aspects, connectivity aspects, power aspects, performance aspects, architecture aspects, cost aspects, and so forth.

Although the present disclosure provides major advantages for the design of VLSI circuits, it will be appreciated that the present disclosure may apply to any integrated circuit.

The method 400 may be applied to reconfigure the reconfigurable integrated circuit 300.

The reconfigurable integrated circuit 300 may be for example a VLSI integrated circuit comprising combinatorial logic blocks/cells, or sequential logic block, or a combination of the two and the method 400 may be applied to the circuit 300 to correct mistakes which emerge late in the design phase. For example, the designer may realize during the testing phase that a logic cell needs replacement. In this case the spare neural network cell may be configured to function as the missing logic cell.

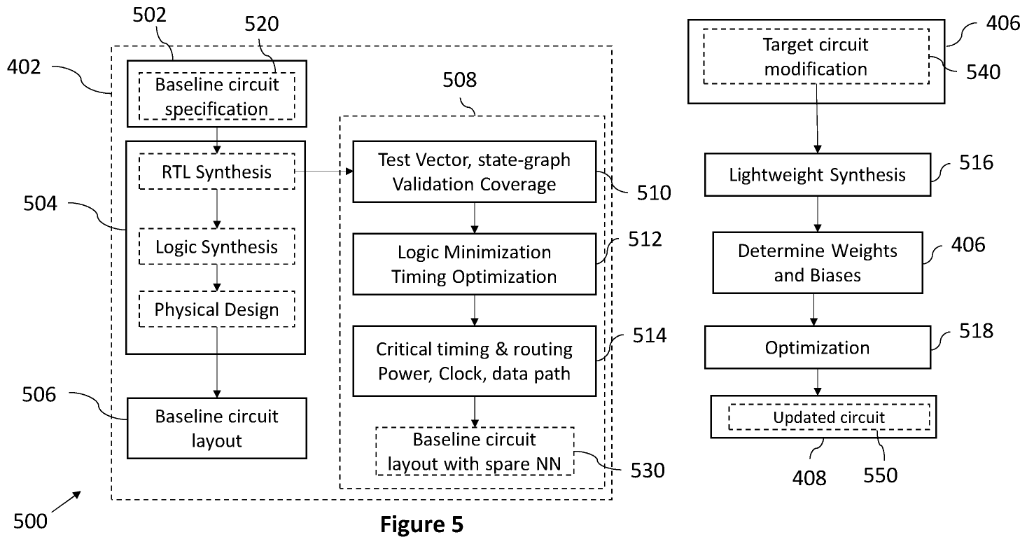

FIG. 5 is a schematic diagram of a method 500 of reconfiguring an integrated circuit, according to a first embodiment of the method 400 of FIG. 4. Common reference numerals and variables between Figures denote common features.

The method 500 illustrates further optional steps of the method 400. At step 502, a baseline circuit specification 520 is provided. The baseline specification 520 may be for example a computer-readable document, such as a netlist file; or, it may be a non-digital document.

At step 504, the baseline specification 520 undergoes one or more synthesis processes. For example, the baseline specification 520 may undergo transfer level (RTL) synthesis, logic synthesis and physical design synthesis. A baseline circuit layout 506 is generated at the end of step 504.

The baseline circuit layout may comprise one or more of: combinational logic blocks; sequential logic blocks; and other digital circuits such as memory access blocks; digital signal processing (DSP) blocks; analog to digital conversion blocks; mixed signal closed-loop controls; neural network blocks for inferencing, classification, linear regression; and so forth.

At step 508, at least one neural network is added to the baseline circuit layout and a modified layout 530 with spare NN cells is obtained. Step 508 may comprise various stages of optimization such as, for example, using test vectors and state-graphs to identify the validation coverage of the circuit (step 510); identifying ECOs which are most likely to be required in future; performing logic minimization and timing optimization to identify what spare NN cell configuration and corresponding NN inputs would enable to implement the maximum number of said most likely ECO without impacting the critical timing paths of the baseline circuit (step 512); optimizing critical timing and routing power, clock and data paths (step 514).

A digital circuit design is complete when the digital circuit performs according to specification. The specification is typically incomplete, that is, some possible input combinations may not been specified (the designer may simply define them as “DON'T CARE”). By looking at the logical function coverage of the circuit, that is at how many combinations are unspecified, it may be possible to identify what ECOs may be requested in future, since ECOs will most likely be related to undefined logical functions. As an example, a digital circuit may be designed such that only one of three outputs of a digital block is used in subsequent processing (this could be explicit by connections or apparent based on the logical function). The other two unused outputs would then be good candidates for potential ECO. Another approach to identify most likely ECOs may be to look at the assertions used in digital verification methodology and check if these assertions cover all possible combinations for the logical function. Any area where the assertions do not have adequate coverage may be a good candidate for future ECOs.

A spare NN cell may then be added to the baseline specification in a manner that would provide additional functionality that is not covered in the baseline specification. It is done in a manner that would make it possible to implement a future ECO. This is achieved by looking at coverage of the circuit in step 510 and identify the potential ECO(s) that increase this coverage.

With reference to FIG. 3, the baseline specification 520 of FIG. 5 may be a specification for the integrated circuit 300 and the adaptive neural network cell added to the baseline specification may be the adaptive neural network cell 304 of FIG. 3.

The adaptive neural network cell (304) is initially in a passive, or inactive state; that is, the spare neural network cell is configured to be in a state which does not substantially impact the functionality of the remaining blocks and components of the integrated circuit. In other words, the spare neural network cell could be removed from the circuit and the circuit logic functionality would not change.

At step 406, a target circuit modification 540 is identified. Then step 406 and 408 allow to activate the adaptive neural network cell (304) in order to achieve the required modification or correction. The target circuit modification 540 may be identified for example following an ECO which is generated by a circuit designer because of an error which emerges during the post-silicon or post tape-out testing and debugging of the IC; or, it may be identified because of a new functionality not previously considered in the design becomes necessary to satisfy the IC users; or because of timing and power constraints changes, and so forth.

At step 406 the neural network (308) implemented by the digital NN circuit (306) of the adaptive NN cell (304) is trained, via a processor, in order to determine a set of weights associated with target outputs for the target circuit modification 540. Training the NN 308 at step 406 may comprise: identifying a subset of inputs among all the inputs connected to the spare NN cell which contribute to the desired functional outcome; identifying a subset of outputs of the spare NN cell which contribute to the desired functional outcome; and training the NN with all possible combinations of inputs and output in said subsets which provide the desired functional outcome, such that the NN is substantially over-trained using all combinations of input/output signals which may be possible during circuit operation and the trained NN will have 100% accuracy. In some cases, it might be possible to determine the weights and biases of the NN by direct methods based on the functional outcome desired from the subset of the inputs.

This extreme form of over-training substantially allows to fully map the outputs of the adaptive NN cell 304 to any of the inputs of the adaptive NN cell that contribute to the desired functional outcome such that the weights obtained via training the NN 308 provide 100% accuracy for any possible input combinations.

The method 500 may comprise adding multiple space NN cells to the baseline circuit layout, that is the modified circuit layout 530 may comprise more than one spare NN cell.

The method 500 may further comprise, upon a target circuit modification 540 being provided performing a lightweight synthesis according to the updated specification 540 in order to: based on the space NN cells and connections to said cells which are available in the layout 530, decompose/break down the target circuit modification into smaller logic functions, each of which can be implemented by a specific spare NN cell. This may comprise determining which connections can be used to achieve the target circuit modification and the corresponding logic function that is required. There will typically be multiple different implementations using different combinations of connections, logic function and spare NN cells to achieve the target circuit modification.

Lightweight synthesis allows to identify the most optimal implementation based on the connections and spare cells available in the layout 530.

At step 408 the one or more spare neural network cells are configured with the set of weights obtained at step 406 in order to obtain an updated circuit 550 which achieves the target circuit modification, such that an updated circuit 550 is obtained. The updated circuit 550 obtained at step 408 will be compliant with the updated specification 540. After determining the one or more set of weights associated with the target circuit modification, further optimization may be carried out to improve the circuit performance (timing, power, etc).

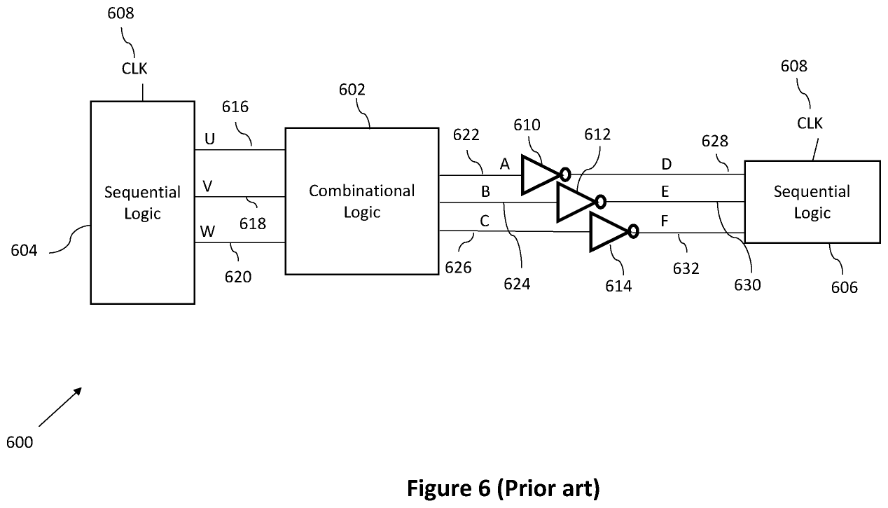

FIG. 6 is a schematic diagram of a configurable integrated circuit 600 according to the prior art.

The circuit 600 comprises a combinational logic block 602, a first sequential logic block 604, and a second sequential block 606. The logic blocks 604, 602 and 606 are coupled in series.

The sequential block 604 is configured to provide in output three signals, 616 (U), 618 (V) and 620 (W), which are fed in input to block 602. The combinational logic block 602 is configured to provide in output three signals 622 (A), 624 (B) and 626 (C). Signal 622 (A) is provided in input to an inverter 610 which outputs a signal 628 (D). Signal 624 (B) is provided in input to an inverter 612 which outputs a signal 630 (E). Signal 626 (C) is provided in input to an inverter 614 which outputs a signal 632 (F). The signals 628 (D), 630 (E) and 632 (F) are fed in input to the second sequential block 606.

The sequential blocks 604 and 606 receive in input a clock signal 608.

In this specific example, the signals 616 (U), 618 (V), 620 (Ws), 622 (A), 624 (B), 626 (C), 628 (D), 630 (E) and 632 (F) are logic signals, that is, they can only have a logic 0 or logic 1 value.

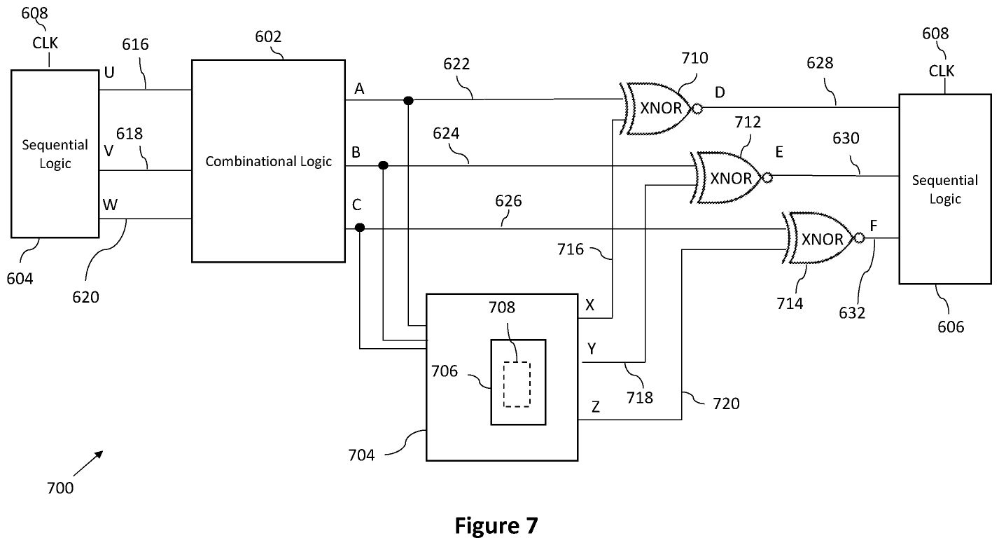

FIG. 7 is a schematic diagram of a configurable integrated circuit 700 according to a first embodiment of the circuit 300 of FIG. 3. Common reference numerals and variables between Figures denote common features.

The circuit 700 is similar to the circuit 600 of FIG. 6, however it comprises three XNOR gates 710, 712 and 714 instead of inverters 610, 612 and 614. The circuit 700 further comprises an adaptive neural network cell 704.

The sequential block 604 is configured to provide in output the three signals 616 (U), 618 (V) and 620 (W) which are fed in input to block 602. The combinational logic block 602 is configured to provide in output three signals 622 (A), 624 (B) and 626 (C). Signal 622 (A) is provided in input to an inverter 610 which outputs a signal 628 (D). Signal 624 (B) is provided in input to an inverter 612 which outputs a signal 630 (E). Signal 626 (C) is provided in input to an inverter 614 which outputs a signal 632 (F). The signals 628 (D), 630 (E) and 632 (F) are fed in input to the second sequential block 606.

The sequential blocks 604 and 606 receive in input a clock signal 608.

The adaptive neural network cell 704 receives in inputs the signal A, B and C and provides in output three corresponding signals X (716), Y (718) and Z (720). The first XNOR gate 710 is configured to receive in input the signals A and X; the second XNOR gate 712 is configured to receive in input the signals B and Y; and the third XNOR gate 714 is configured to receive in input the signals C and Z.

The adaptive neural network cell 704 is a spare cell which may be in a passive (inactive) state or in an active state. The cell 704 is configured such that when the cell 704 is in the passive state, the circuit 700 works in the same way as the circuit 600. In particular, when the cell 704 is in the passive state, it is configured such that the outputs X, Y and Z are always zero. Hence the XNOR gate 710 will act as an inverter for signal A, the XNOR gate 712 will act as an inverter for signal B and the XNOR gate 714 will act as an inverter for signal C.

If in response to an ECO it is determined that a specific circuit modification must be implemented, for example in the functionality of one of logic block 602, then the neural network 708 can be trained or configured in order to determine the weights which allow to achieve the target circuit modification.

With reference to the method of FIG. 5, the baseline circuit layout 506 may correspond for example to the circuit 600 of FIG. 6. The baseline circuit layout with spare neural network cell 530 may correspond to the circuit 700 prior to the NN cell 704 being configured with the weights to achieve the target circuit modification, that is, when the adaptive NN cell 704 is in the passive, or inactive, state. The update circuit 550 may correspond to the circuit 700 when the spare neural network cell 704 is active, that is, when the spare neural network cell 704 has been configured with weights which allow to achieve the target circuit modification 540.

The circuit 700 of FIG. 7 allows to implement a wide range of modifications or corrections to the circuit layout following an ECO with a minimum increase in circuit complexity. By simply forcing the outputs of the spare NN cell to zero, the functionality of the circuit path on which the spare NN cell is placed is not impacted; and if a change must be implemented, the neural network cell 708 can easily be trained to determine the weights which must be implemented in the digital NN circuit 706 in order to achieve the desired functionality.

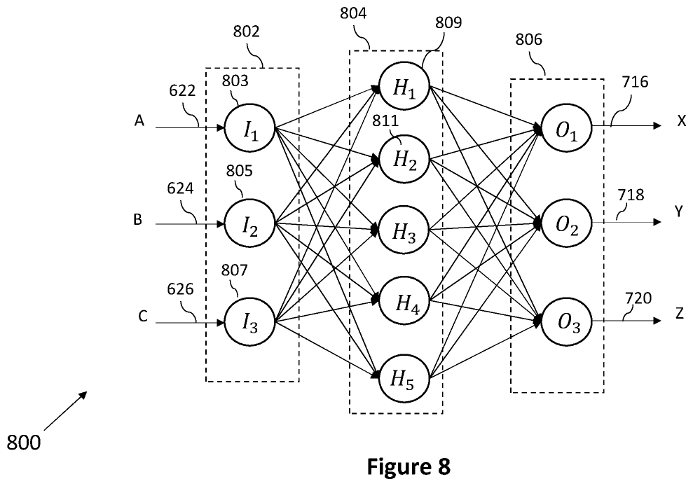

The neural network 708 may have different neural network topologies. A specific example is shown in FIG. 8.

FIG. 8 is a schematic diagram of a neural network topology according to a specific embodiment of the neural network 708 of FIG. 7. Common reference numerals and variables between figures denote common features.

In this specific example, the neural network 708 has an input layer which has three input nodes Iᵢ (802), a hidden layer which has five hidden nodes Hₖ (804); and an output layer which has three output nodes Oⱼ (806), where i=1 . . . N, j=1 . . . M and k=1 . . . L. In the example of FIG. 8, N=M=3 and K=5, however in other topologies the number of inputs may be different from the number of outputs.

The neural network 708 has: weights W_{i,k} for i=1 . . . N and k=L wherein the weight W_{i,k} corresponds to the connection between the i^{th} input and the k^{th} hidden node; weights W_{k,j}, for k=1 . . . L and j=M wherein each weight W_{i,k} corresponds to the connection between the k^{th} hidden node and the j^{th} output. Each hidden node further has a corresponding bias Bₖ; and each output node has a corresponding bias Bⱼ. For a specific set of weights and biases values, the neural network provides specific outputs for each set of inputs.

It will be appreciated that the number of layers as well as the numbers of nodes in each layer, may vary from embodiment to embodiment.

In some embodiments, the neural network 708 is a deterministic neural network, that is, all the possible combinations of inputs which may be fed to the neural network are known and the neural network is trained using all the possible combinations such that its behavior is fully deterministic, that is, a given set of inputs always produced the same set of output.

The neural network 708 may for example be configured such that the input nodes and output nodes are binarized, that is, they can only take on a logic 1 or logic 0 value. Binarized neural network are discussed for example by Simons et al. in “Review of Binarized Neural Networks. Electronics. 2019.

With reference to FIG. 7, where the neural network receives in input the binary signals A, B and C, then all the possible input nodes combinations are given by:
A=0 B=0 C=0
A=0 B=0 C=1
A=0 B=1 C=0
A=0 B=1 C=1
A=1 B=0 C=0
A=1 B=0 C=1
A=1 B=1 C=0
A=1 B=1 C=1

The corresponding outputs X, Y and Z for each input combination can be determined based on the target circuit modification and the neural network may be trained with all the possible inputs and outputs set in order to determine the weights which provide the target circuit modification.

In the example of FIG. 7, the neural network 708 has binary inputs and outputs, however many variations of the above neural network topology and circuit implementation are possible. For example, the digital NN circuit 706 may be configured to implement a neural network 708 where the inputs and outputs of the neural network are logic signals which can take one of three logic values (e.g. −1, 0, +1), instead of only being 0 or 1.

The inputs, outputs, biases and weights of the neural network may have quantized values, where the quantized values can have any number of quantization levels and the number of quantization levels may be different for the inputs, outputs, weights and biases.

In preferred embodiments, the neural network 708 will have either binary or ternary inputs and outputs. This is preferred in order to simplify CMOS logic circuit implementation that can be realized in the smallest silicon area with most flexible functional coverage. A neural network having binary inputs and outputs may be referred to hereinafter also as a “binary neural network”.

As an example, in a binary neural network having the topology illustrated in FIG. 8, the hidden layer nodes may be computed according to:

$$\begin{matrix}{Σ}_{k} = {\sum }_{i = 1}^{3} {I}_{i} \times {w}_{i , k} & {⟹}^{fo r k = 1 to 5}\end{matrix} \{ \begin{matrix}if {Σ}_{k} > - {B}_{k} then {H}_{k} = 1 \\ \begin{matrix}else & {H}_{k} = 1\end{matrix} \\ \end{matrix} \qquad ( 1 )$$

and the output nodes are computed according to:

$${Σ}_{j} = {\sum }_{k = 1}^{5} {H}_{k} * {w}_{k , j} \{ \begin{matrix}if {Σ}_{j} > - {B}_{j} then {O}_{j} = 1 \\ \begin{matrix}else & {O}_{j} = 0\end{matrix}\end{matrix} \qquad ( 2 )$$

The above equations may vary for different embodiments.

As previously mentioned, such binary neural network may be implemented by the digital NN circuit 706 of circuit 700. The circuit 706 be initially configured such that all the output nodes O₁, O₂ and O₃ are zero, that is, the signal X, Y and Z which are coupled respectively to the first, second and third output of the NN are zero.

Then, in response to an ECO, the binary neural network can be trained to identify the weights which allow to achieve a specific target modification. In some embodiment, the digital NN circuit 706 may be configured such that the output X implements one of the following logic functionalities:

| INPUT | X | D |
|---|---|---|
| A | 0 (NN cell inactive) | NOT(A) |
| A | 0 | NOT(A) |
| | 1 | A |
| A | A | 1 |
| A | NOT(A) | 0 |

For example, if an engineering change order requires the signal D of integrated circuit 700 to always be in a logic 1, then the binarized neural network can be trained such that it works as a unity, that is when A (which is provided to the first input node I₁) is 0, X is −0, and when A is 1, X=1. The weights obtained in the training can then be implemented in the digital neural network circuit 706. The first XNOR gate 710 will receive in input two identical signals and will then return 1 for any value of A.

If for example the ECO requires the signal D to be equal to A, then the binarized neural network can be configured such that for X=1 based on the inputs A, B, C, U, V, W as determined by ECO; and so forth.

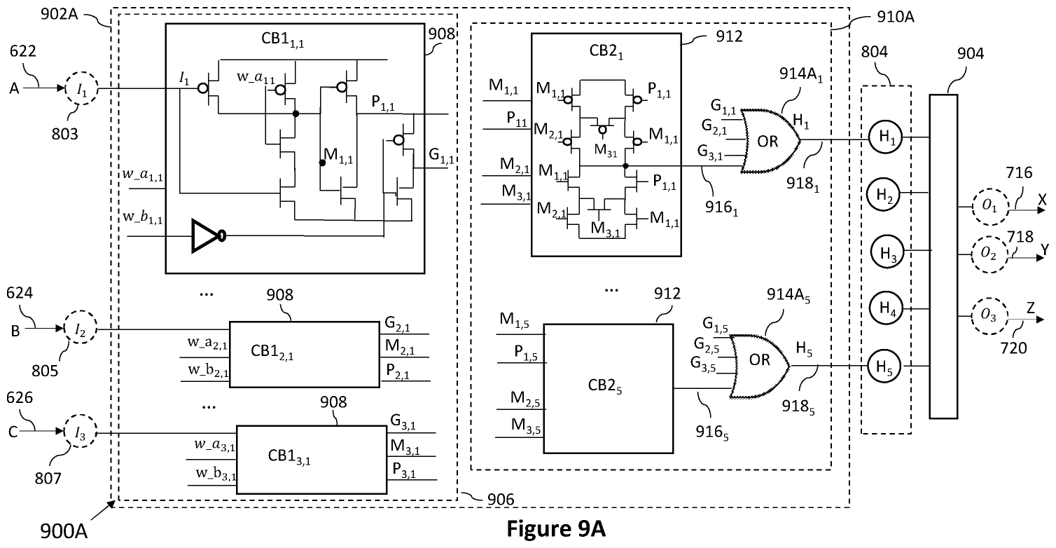

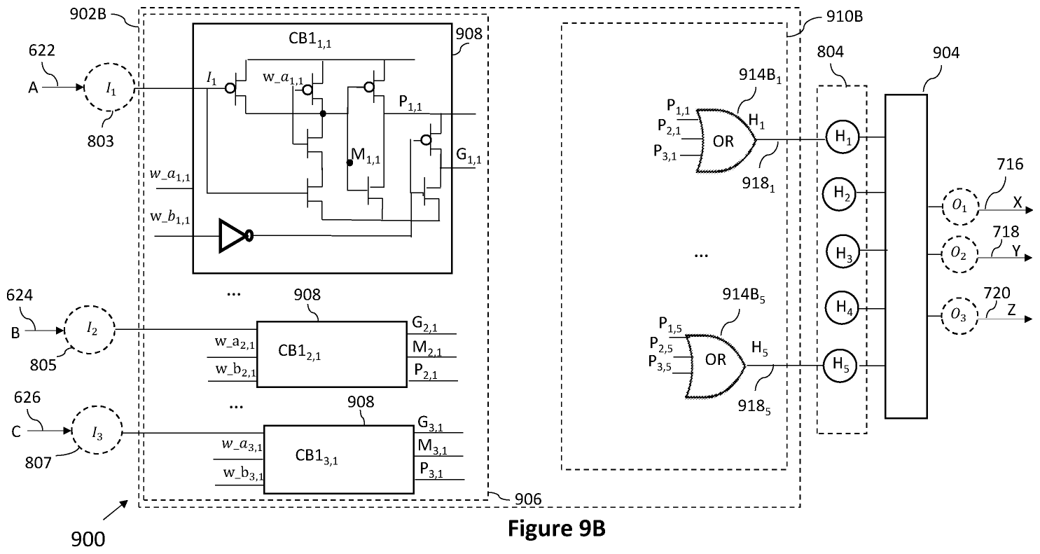

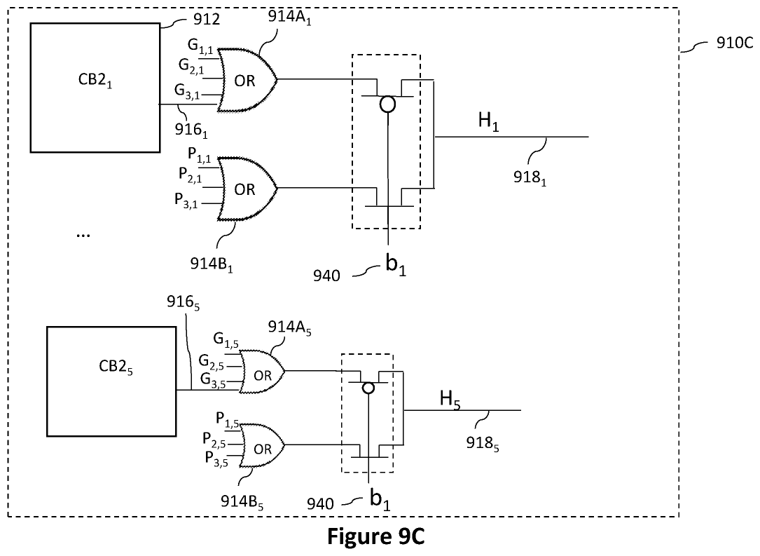

FIG. 9A is a schematic diagram of a digital NN circuit 900A according to a specific embodiment of the digital neural network circuit 706. Common reference numerals and variables between Figures denote common features.

In this specific embodiment the digital NN circuit implements a neural network which has the topology 800 shown in FIG. 8, binary inputs Iᵢ and outputs Oⱼ which can only take the logic values 0 or 1, and operating according to equation (1) and (2) above. In this specific embodiment the digital neural network circuit implements a neural network which has a step activation function with a binary output and the threshold for the step activation function is 1.5 (all biases are −1.5). In this specific embodiment the weights of the neural network connection between the input nodes and the hidden node are quantized and can only take on the values {0, 1, 2}.

Although some connections are not shown to aid visual clarity, it will be appreciated that lines which are labelled with the same signal are meant to have connection in between them.

For each input Iᵢ the corresponding weight W_{i,k} is encoded in the signal w_a_{i,k} and w_b_{i,k}. For example, the weight W_{1,1} for the connection between the first input I₁ and the first hidden node H₁ is encoded in the signals w_a₁₁ and w_b_{1,1}. The weight W_{1,2} for the connection between the first input 803 (I₁) and the second hidden node H₂ is encoded in the signals w_a_{1,2} and w_b_{1,2} (not shown). The weight W₂₁ for the connection between the second input I₂ and the first hidden node H₁ is encoded in the signals w_a_{2,1} and w_b_{2,1}; and so forth.

The circuit 900A comprises a first circuit portion 902A to provide the hidden nodes values Hₖ (k=1 . . . 5) and a second circuit portion 904 to provide the output values Oⱼ (j=1 . . . M).

The first circuit portion comprises a first set 906 of stage-1 circuits CB1_{i,k} (908) wherein each stage-1 circuit CB1_{i,k} corresponds to a connection between the i^{th} input node and the k^{th} hidden node of the neural network 708. Since in this specific embodiment i=1 . . . 3 and k=1 . . . 5, the plurality 906 of stage-1 circuits 908 contains 15 stage-1 circuits CB1_{i,k}.

The circuit 900A further comprises a plurality 910A of stage-2 circuits CB2ₖ (912), wherein each stage-2 circuit CB2ₖ correspond to the kₜₕ hidden node Hₖ.

Stage-1 circuit CB1_{1,1}, which corresponds to the connection between the first input node I₁ and the first hidden layer node 809, is configured to receive in input the signals w_a_{1,1}, and w_b,_{1,1}. Stage-1 circuit CB1_{1,2}(not shown), which corresponds to the connection between the first input node I₁ and the second hidden layer node Hz, is configured to receive in input the signals w_a_{1,2}, and w_b_{1,2}; and so forth.

The embodiment of FIG. 9A illustrates a very compact implementation for stage-1 circuits CB1_{i,k} and stage-2 circuit CB2ₖ. Stage-1 circuits CB1_{i,k} and stage-2 circuit CB2ₖ may be easily provided as library cells.

The specific implementation of the stage-1 circuits and stage-2 circuits of FIG. 9A is shown only for stage-1 circuit CB1_{1,1} and stage-2 circuit CB2₁; however it will be appreciated that further circuits CB1,_{i,k} and CB2ₖ will have analogous implementations.

Each state-1 circuits CB1_{i,k} is configured to provide a first output signal G_{i,k}, a second output signal M_{i,k} and a third output signal P_{i,k}, where the third output signal P_{i,k} is the opposite of signal M_{i,k}. The signal M_{i,k} corresponds a logic NAND between input signal I₁ and weight signal w_a_{i,k}. The signal P_{i,k} corresponds a logic AND between input signal I₁ and weight signal w_a_{i,k}. The signal G_{i,k} is equivalent to a logic AND function between weight signal w_b_{i,k} and signal P_{i,k}.

Each stage-2 circuit CB2ₖ (912) have one or input which may be coupled to one or more of the signals G_{i,k}, M_{i,k} and P_{i,k}.

In the specific embodiment of FIG. 9A, stage-2 circuits CB2ₖ are configured to implement a carry bit output of a 1-bit adder having three 1-bit inputs and one carry-bit output 916ₖ. The three 1-bit inputs in a conventional 1-bit adder with carry would consist of two 1-bit inputs and 1-bit carry of the previous stage. In this embodiment, the carry-bit output circuit of an adder with three 1-bit inputs is used. There is no difference between the three inputs.

Specifically, for each k, the stage-2 circuit CB2ₖ is configured to receive in input the second output signal M_{i,k} and the signal P_{1,k}, of each circuit 908 corresponding to the k^{th} hidden node. For example, stage-2 circuit CB2₁ which corresponds to the first hidden node H₁ receives in input the signals M_{1,1} and P_{1,1} from stage-1 circuit CB1_{1,1}, the signals M_{2,1} from stage-1 circuit CB1_{2,1}; and the signals M_{3,1} from stage-1 circuit CB1_{3,1}; the stage-2 circuit CB2₂ which correspond to the second hidden node H₂ receives in input the signals M_{1,2} and P_{1,2} from stage-1 circuit CB1_{1,2}, the signals M_{2,2} from stage-1 circuit CB1_{2,2}; and the signals M_{3,2} from stage-1 circuit CB1_{3,2}; and so forth.

Overall, the workings of the pluralities of stage-1 circuits 908 and stage-2 circuits 912 allows to compute the summation in equation (1). Each stage-1 circuit CB1_{i,k} is configured to provide one or more output signals associated with a product function for the corresponding addend in the summation of equation 1; and each stage-2 circuits is configured to receive one or more outputs signals from each stage-1 circuit associated with the corresponding hidden node and to provide a value of the corresponding hidden node. In the specific example of FIG. 9A, each stage-1 circuit CB1_{i,k} provides a pair of signals G_{i,k}, M_{i,k} which encodes the term Iᵢ×w_{i,k}.

The carry bit output signal 916₁ of stage-2 circuit CB2₁ is provided in input to an OR gate 914A₁ which also receives the signal G_{i,1} (i=1 . . . 3). The output 918₁ of the OR gate 914A₁ provides H₁ according to equation (1). Similarly, each other stage-2 circuit CB2ₖ provides in output a signal which is fed into an OR gate receiving in input the three signals G_{i,k} (i=1 . . . 3) and providing in output the hidden node value Hₖ.

Each OR gate 914Aₖ is configured to implement the comparison of equation 2 between the summation Σₖ and the bias Bₖ. In the neural network implemented by the circuit 900A of FIG. 9A, the bias is −1.5 and the OR gate output is set (logic 1) if the summation Σₖ is equal or greater than 2. If any of the signal 916₁, G_{1,1}, G_{2,1} or G_{3,1} are set to logic 1 then the weighted sum of the signals is at least two, hence greater than the step activation threshold of 1.5 and the output 918₁ of the OR gate 914A₁ will be set (logic 1) independently on the other inputs of gate the OR gate 914A₁. The output of the OR gate 914A₁ provides the value of hidden node H₁.

The output 918₁ of the OR gate 914A₁ provides H₁ according to equation (1). Similarly, each other stage-2 circuit CB2ₖ provides in output a carry bit signal 916ₖ which is fed into an OR gate 914Aₖ receiving in input the three signals G_{i,k} (i=1 . . . 3) and providing in output a signal 918ₖ corresponding to the value of hidden node Hₖ.

Circuit 900 further comprises a second portion 904 configured to receive in input the hidden layer signal H₁ through H₅ and to output three output signals O₁ through O₃. The implementation of the second portion 904 is analogous to that of the first portion 902A with the hidden nodes Hₖ acting as inputs for the activation function of the output layer. The activation function may again be chosen to be a step activation function with biases −1.5, in which case the implementation of the second portion 904 is analogous to that of the first portion 902A.

For a neural network where the weights W_{i,k} can only take three values a thermometer-scale implementation may be used to derive the corresponding signals w_a_{i,k}, and w_b_{i,k}, as shown in this table:

| W_{i, k} | w_a_{i, k} | w_b_{i, k} |
|---|---|---|
| 0 | 0 | 0 |
| 1 | 1 | 0 |
| 2 | 1 | 1 |

In other embodiments the weights may have more than 3 quantization level. For example, the weight may have 5 quantization level {−2, −1, 0, 1, 2}.

It will be appreciated that in different implementations, the stage-2 circuits CB2ₖ may be coupled to different signals. In a different embodiment the circuit 900A of FIG. 9A may be modified such that each stage-2 circuit CB2ₖ receives in input the signal P_{2,k} or P_{3,k} instead of the signal P_{1,k} The specific implementation of stage-2 circuits and the connections between stage-2 circuits CB2ₖ and corresponding stage-1 circuits CB1_{i,k} may be chosen based on physical placement of each component on silicon and such as to minimize metal wiring. In some embodiment, each CB2ₖ circuit receives in input only one P_{i,k} signal where i is the index corresponding to the stage-1 circuit which is nearest on silicon to CB2ₖ.

The person skilled in the art will appreciate that the above implementation can be modified to implement any combination of activation function, biases and weight quantization as desired.

For example, FIG. 9B illustrates an example digital neural network circuit 900B implementing a neural network topology identical to that implemented by the circuit of FIG. 9A but with biases equal to −0.5 for the hidden layer. In the embodiment of FIG. 9B, the stage-1 circuits CB1_{i,k} are implemented in a manner identical to the stage-1 circuits CB1_{i,k} of the embodiment of FIG. 9A, however the outputs signals P_{i,k} of the stage-1 circuits are provided rather than the signal G_{i,k} are provided to OR gates 914Bₖ in order to implement the comparison Σₖ>0.5.

In some embodiments, the integrated circuit 900 is further configurable with a set of target biases to achieve the target circuit modification. For example, in some embodiments, the circuit 900A of FIG. 9A may be configured such that both P_{i,k} and G_{i,k} outputs are coupled to OR gates 914Aₖ and 914Bₖ respectively via multiplexing circuitry, such that the circuit can be selectively configured to implement either a NN with bias −1.5 or with bias −0.5. This is illustrated in FIG. 9C which shows an alternative implementation 910C of the second set 910 of stage-2 circuits CB2ₖ. A control signal b₁ (940) allows to selectively couple the output of the OR gate 914Aₖ or the output of the OR gate 914Bₖ to the hidden node Hₖ such that when b₁ is set to logic 1 the bias of the hidden layer of the NN is set to −0.5 and when b₁ is set to logic 0 bias is set to −1.5. Inputs of the circuits CB2ₖ are omitted in this Figure for simplicity.

It will be appreciated that other topologies could be considered in which it is possible to choose from more than two bias values.

It will also be appreciated that in other embodiments the digital neural network circuit may implement a neural network with more than one hidden layers and for each layer the digital neural network circuit may be configurable with different weighs and bias values in a similar way as to what explained with reference to FIGS. 9A, 9B and 9C.

In some embodiments the digital neural network circuit 706 is configured to implement a neural network having the topology 800 and operating according to equation (1) and (2) above with bias Bₖ=−1.5, bias Bⱼ=0 for all j; and in which the weights have 5 quantization levels. Then, the following weights may be used in order for the neural network to implement a unity:

| | H₁ | H₂ | H₃ | H₄ | H₅ |
|---|---|---|---|---|---|
| I₁ | 2 | 0 | 0 | 0 | 0 |
| I₂ | 0 | 2 | 0 | 0 | 0 |
| I₃ | 0 | 0 | 2 | 0 | 0 |
| O₁ | 1 | 0 | 0 | 0 | 0 |
| O₂ | 0 | 1 | 0 | 0 | 0 |
| O₃ | 0 | 0 | 1 | 0 | 0 |

A further example in which the hidden nodes still have biases Bₖ=0 for each k, and the output nodes have biases

$${B}_{j} = \{ \begin{matrix}∓ 1 for j = 1 \\ \pm 1 for j = 2 \\ 0 for j = 3\end{matrix}$$

is shown below:

| | H₁ | H₂ | H₃ | H₄ | H₅ |
|---|---|---|---|---|---|
| I₁ | 1 | 1 | 0 | 0 | 0 |
| I₂ | 1 | 1 | 0 | 0 | 0 |
| I₃ | 1 | −1 | 2 | 0 | 0 |
| O₁ | −1 | −1 | −2 | 0 | 0 |
| O₂ | −1 | −1 | −2 | 0 | 0 |
| O₃ | 0 | 0 | 1 | 0 | 0 |

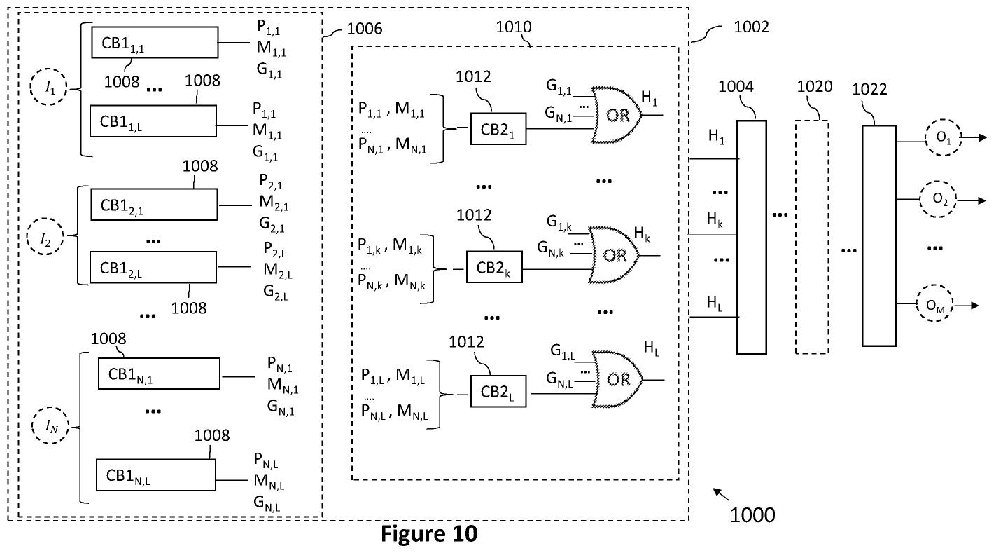

A generalization of the circuit 900A is shown in FIG. 10.

FIG. 10 is a schematic diagram of a digital NN circuit 1000 according to a specific embodiment of the circuit 706. Common reference numerals and variables between Figures denote common features.

In this embodiment the digital NN circuit 706 implements a neural network 708 which has one input layer comprising N nodes Iᵢ, one hidden layer comprising L nodes Hₖ and an output layer comprising M nodes Oⱼ. The neural network of this specific embodiment operates according to equations (1) and (2) above and the weights of the neural network are quantized and can only take the values {0,1,2}.

The circuit 1000 comprises a first circuit portion 1002 analogous to the first circuit portion 902A of FIG. 9A and a second circuit portion 1004 analogous to the second circuit portion 904 of FIG. 9A.

The plurality of stage-1 circuits 1006 comprises N*L circuits CB1 (1008); and the plurality of stage-2 circuits 1010 comprises L circuits CB2 (1012). In this and following figures the weight signals are omitted for simplicity.

The front-end circuits 1006 and 1010 are configured in an analogous way to the plurality of circuits 906 and 910A of FIG. 9A. The outputs of stage-2 circuits 912 are fed to the next NN layers which are implemented by the second portion 1004.

The circuit 1000 may implement a binary NN with more than one hidden layer. For each additional hidden layer, an additional circuit portion 1020 analogous to the first portion 1003 will be required to computed the nodes of the next layer. The output of the last circuit portion 1022 provide the output of the neural network.

In the example illustrated in FIG. 7, the spare NN cell 704 is provided in correspondence of inverter gates, or buffers, 710, 712 and 714. In practice, inverter gates are often used to identify insertion points for spare cells. because they constitute the smallest unit of logic cells in a circuit design. However, the spare neural network cells may also be provided in correspondence of other logic gates or circuit components.

Often, inverter gates are used as the final gate of digital library cells meaning that they are almost ubiquitous in digital circuit design. Inverters gates are generally the simplest functional digital CMOS circuit utilized in digital electronics, consisting merely of a stacked PMOS and NMOS, where the gate terminals of the PMOS and NMOS are coupled together at a node which receives the input signal of the inverter and the drain terminals of the PMOS and NMOS are coupled together at a node which provides the output signal of the inverter. However, more complex logic gates or cells may be used as ending stage of digital library cells and/or insertion points for spare cells.

It will be appreciated that in other embodiments, each XNOR gate 710, 712 and 714 may each receive more than one NN output.

In some embodiments, the outputs X, Y, and Z of the spare neural network cell 704 and the outputs A, B and C of the combinational logic block 702 may be coupled to a different type of logic gate, rather than an XNOR gate. With reference to the method 500, in some embodiments step 508 may comprise:
identifying an inverter gate (e.g. 610) in a baseline circuit layout;
replacing the inverter gate with an XNOR gate(for example the XNOR gate 710 of FIG. 7); and
adding a spare neural network cell (e.g. cell 704) to the circuit layout, where one or more outputs of the spare NN cells are provided in input to the XNOR gate.

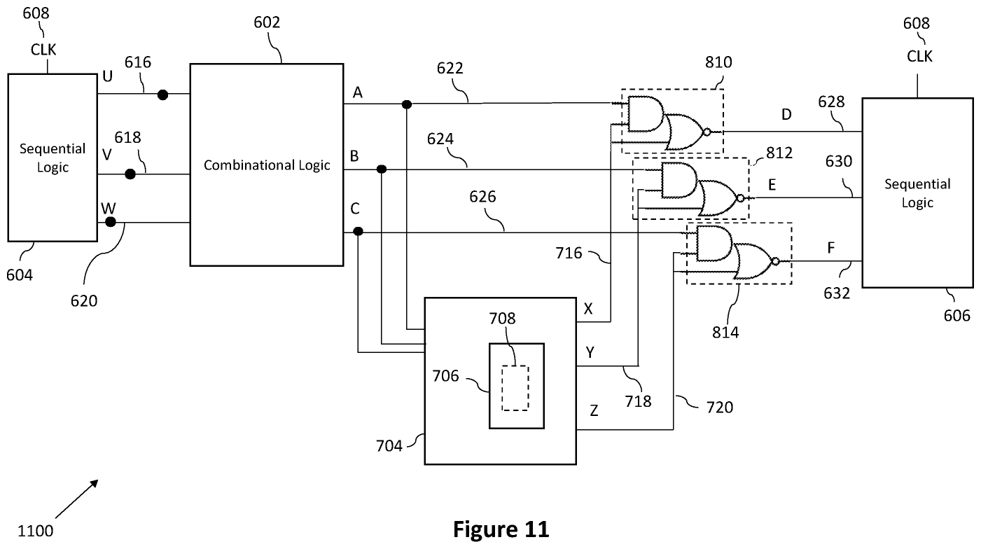

In other embodiments, step 508 may comprise replacing an inverter gate with an AND-OR-invert (AOI) gate. This is illustrated in FIG. 11.

FIG. 11 is a schematic diagram of a configurable integrated circuit 1100 according to a second embodiment of the circuit 300 of FIG. 3. Common reference numerals and variables between Figures denote common features.

In this embodiment, the inverter gates 610, 612 and 614 of circuit 600 are replaced by AOI gates 810, 812 and 814 respectively, and the spare NN cell 704 is configured such that:
when the spare NN cell 704 is passive (not needed in the circuit layout), the digital NN circuit 706 is configured to work like a unity, that is, each output X, Y, Z is equal to the corresponding input A, B, C respectively; and
when the spare NN cell 704 is activated in response to an ECO, the digital NN circuit 706 is configured to work with the weights obtained via training the NN to implement the target circuit modification.

The implementation of circuit 700 has the advantage that the output of the neural network cell 704 do not need to have a valid signal (1) when the active cell is in the passive state, whereas in the embodiment illustrated in FIG. 11 the outputs of the neural network must always be valid, even when the spare NN cell is not in use, in order for the circuit to function correctly. In digital circuits signals can be unknown until they are actively set/reset. It is important to have all input nodes be actively set/reset before a CLOCK is applied after a RESET is released. In the embodiment of FIG. 7 {X, Y, Z} can be set to “0” when the spare NN cell is not in use; whereas in the embodiment of FIG. 11, it is necessary for X, Y and Z to be actively set to a logic value.

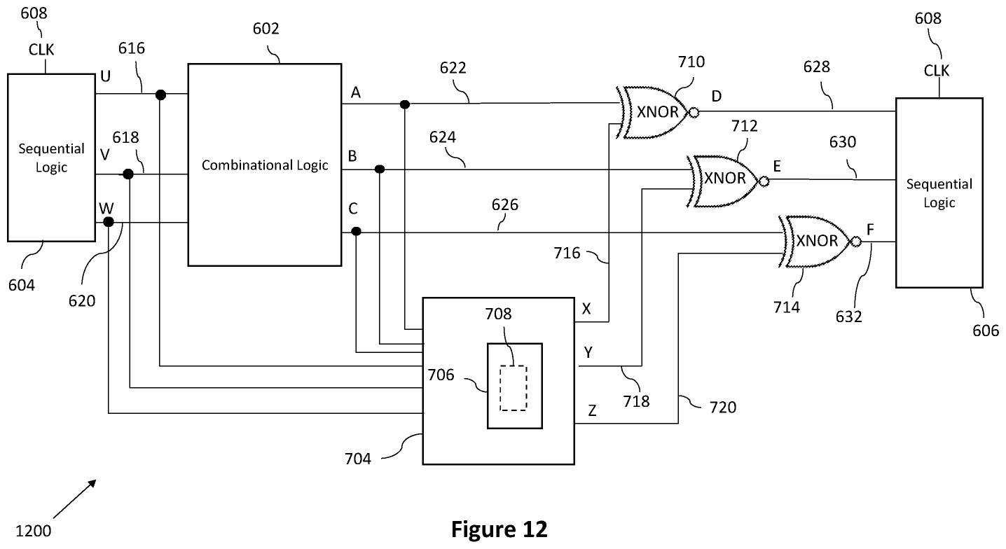

In some embodiments the spare neural network cell 706 may receive in input further signals of the circuit 700. For example, the spare neural network cell 706 may receive in input both the output signals A, B, C of the combinational logic block 602 and the output signals U, V, W of the sequential logic block 604, as shown in FIG. 12, which is a schematic diagram of an integrated circuit according to a third embodiment of the circuit 300 of FIG. 3.

In some embodiments, the circuit 700 may be configured such that: the spare neural network cell 704 receives in input the signals U, V, W of the sequential logic block 604 but not the outputs A, B, and C of the combinational logic block 602; and the digital neural network circuit 706 is configured to “bypass” the combinational logic block 602; that is, the neural network 708 is trained such that the digital circuit 706 replaces the combinational logic block 602.

It will be appreciated that an IC may contain many logic blocks coupled to each other in various ways and that multiple adaptive neural networks cells analogous to the adaptive NN cell 704 may be interposed between any two blocks. Each adaptive NN cell may be interposed between more than two blocks, that is, each adaptive neural network cell may receive in input signals from more than one block and provide outputs to more than one block. Each adaptive neural network cell may comprise a digital NN circuit which is configured to implement a neural network having the same or a different topology from that of the other adaptive NN cell cells.

In some embodiments, the adaptive NN cells are configured to implement supplementary logic functions that produce the change requested via an ECO but leave unchanged the functionality of the existing active combinational and/or logic blocks, whereas in other embodiments, the use of adaptive NN cells allows for the circuit functionality to be modified and for entire combinational and or sequential blocks to be bypassed.

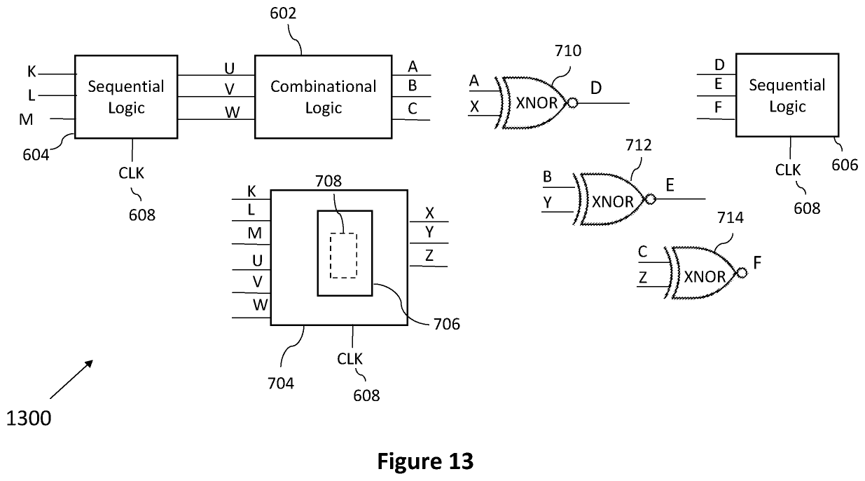

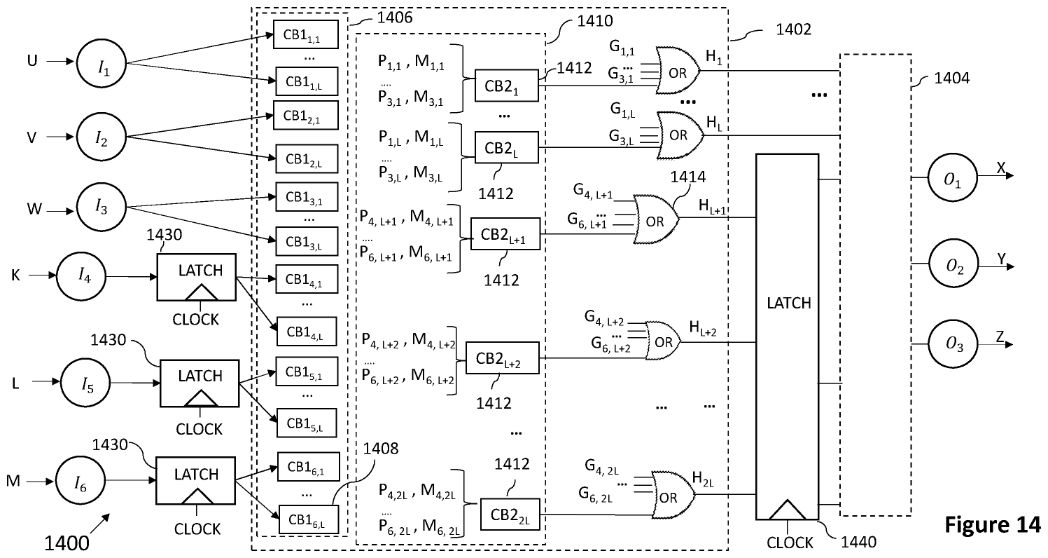

Adaptive digital NN cells can be used to provide any desired combinational logic or sequential logic functional changes. The input(s) of a spare NN cell can be taken from any node between two clocked sequential logic blocks (such as A, B, C, U, V, W in FIG. 7); or, it may be taken from any node at the input of a sequential logic block (such as K, L, M in FIG. 13), in which case the spare NN cell will receive data from the previous clock and therefore the data will need to be latched prior to be combined with the data of any node from the current clock (such as U, V, W or A,B,C in FIG. 13). Whenever the path on which the spare digital NN cell is located involves a sequential logic cell/block, then appropriate clock-adjustment components must be coupled to the spare neural network cells to ensure correct alignment of all signals, as illustrated in FIG. 13 and FIG. 14.

FIG. 13 is a schematic diagram of a configurable integrated circuit according to a fourth embodiment of the circuit 300 of FIG. 3. FIG. 13 illustrates an example implementation in which the adaptive neural network cell 704 receives in input the input (K, L, M) and output (U, V, W) signals of sequential logic cell 604. Common reference numerals and variables between Figures denote common features. In this embodiment, the inputs of the neural network cell 704 must be time-aligned prior to being fed to the neural network 708, since they correspond to different clocks.

FIG. 14 is a schematic diagram of a digital neural network circuit 1400 according to a specific embodiment of the digital NN circuit 706 of FIG. 13. Common reference numerals and variables between Figures denote common features.

In this specific embodiment the adaptive NN cell receives in input the input signals K, L, M of the sequential logic block 604 and the output signals U, V, W of the sequential logic block 604 (inputs of the combinational logic block 602) of circuit 1300.

The circuit 1400 implements a neural network having an input layer with 6 input I₁, I₂, I₃, I₄, I₅, I₆, receiving respectively signals U, V, W, K, L, M; one hidden layer with hidden nodes H₁ . . . . H_{L}, H_{L+1} . . . H_{2L}; and an output layer with three output nodes O₁, O₂ and O₃, providing signals X, Y and Z respectively.

In this specific embodiment, there are 2L nodes in the first hidden layer following the inputs. Nodes H₁ through H_{L} are connected to inputs U (I₁), V (I₂), W (I₃) and perform the first stage of combinational logic ECO. Nodes H_{L+1} through H_{2L} are connected to inputs K (I₄), L (I₅), M (I₆) and they perform the first stage of sequential logic ECO.

Circuit 1400 comprises a first circuit portion 1402 to provide the hidden nodes values Hₖ (k=1 . . . 2L) and a second circuit portion 1404 analogous to circuit portion 904 of FIG. 9A to provide the output values X, Y and Z.

The first circuit portion comprises a first set 1406 of stage-1 circuits CB1_{i,k} (1408) analogous to stage-1 circuits 908 of FIG. 9A wherein each stage-1 circuit CB1_{i,k} corresponds to a connection between the i^{th} input node and the k^{th} hidden node. The circuit 1400 further comprises a plurality 1410 of stage-2 circuits CB2ₖ (1412) analogous to stage-2 circuit 912 of FIG. 9A, wherein each circuit block CB2ₖ correspond to the kₜₕ hidden node Hₖ

In order to time-align the signals K, L, M which are provided to input nodes I₄, I₅ and I₆ respectively with the signals U, V, W which are provided to input nodes I₁, I₂ and I₃ respectively, the signals K, L, M are fed into latches 1430 prior to being provided to their corresponding stage-1 circuits 1408.

The latches 1430 ensure that the inputs of the neural network are properly synchronized. K, L, M inputs are latched synchronously with the sequential logic block 604 of FIG. 13 so that combinational logic outputs A, B, C and X, Y, Z are processed in the correct clock cycle.

The activation function for the nodes H₁ through H_{L} may be given by:

$$\begin{matrix}{Σ}_{k} = {{\sum }^{3}}_{i = 1} {I}_{i} \times {w}_{i , k} & {⟹}^{fo r k = 1 to L}\end{matrix} \{ \begin{matrix}if {Σ}_{k} > - 1.5 then {H}_{k} = 1 \\ \begin{matrix}else & {H}_{k} = - 1\end{matrix} \\ \end{matrix}$$

The activation function for the nodes H_{L+1} through H_{2L} may be given by:

$$\begin{matrix}{Σ}_{k} = {{\sum }^{4}}_{i = 1} {I}_{i} \times {w}_{i , k} & {⟹}^{fo r k = L + 1 to 2 L}\end{matrix} \{ \begin{matrix}if {Σ}_{k} > - 1.5 then {H}_{k} = 1 \\ \begin{matrix}else & {H}_{k} = - 1\end{matrix} \\ \end{matrix}$$

It will be appreciated however that other NN topologies may be adopted in which the number of hidden nodes connected to the latched inputs is no equal to the number of nodes connected to the non-latched inputs. Moreover, in different topologies the neural network may be configured such that the hidden nodes of the first hidden layer may be connected to both latched and non-latched inputs. In the specific embodiment illustrated in FIG. 14, this functionality is left for the consecutive hidden layers.

The specific embodiment of FIG. 1400 further comprises a latch 1440 located after the first hidden layer. Latch 1440 at the output of the first hidden layer is optional and can be used to help timing closure of the circuit design. If latch 1440 is used with a clock signal which is equal to inverted clock signal 608 (or if it is omitted), it will allow the NN outputs X, Y, Z to be available within the same clock cycle as the signals A, B, C, that is, the signals A, B, and C will be time-aligned with the signal X, Y, Z. If latch 1440 is used with the clock signal 608 the signals A, B, C, will be time aligned with the signals X, Y, Z from the previous clock cycle.

In one embodiment of this disclosure latch 1440 can use inverted clock to synchronize the latched inputs at half clock cycle. In another embodiment latch 1440 can use non-inverted clock to have the sequential logic ECO outputs H_{L+1} through H_{2L} made available in the next clock cycle.

The output(s) of the adaptive NN cell can be connected to any node between two clocked sequential logic blocks (such as D, E, F in FIG. 7). This insertion can be made by replacing inverters with XNOR gates as shown in FIG. 7, or by replacing inverters with AOI gates, as shown in FIG. 11.

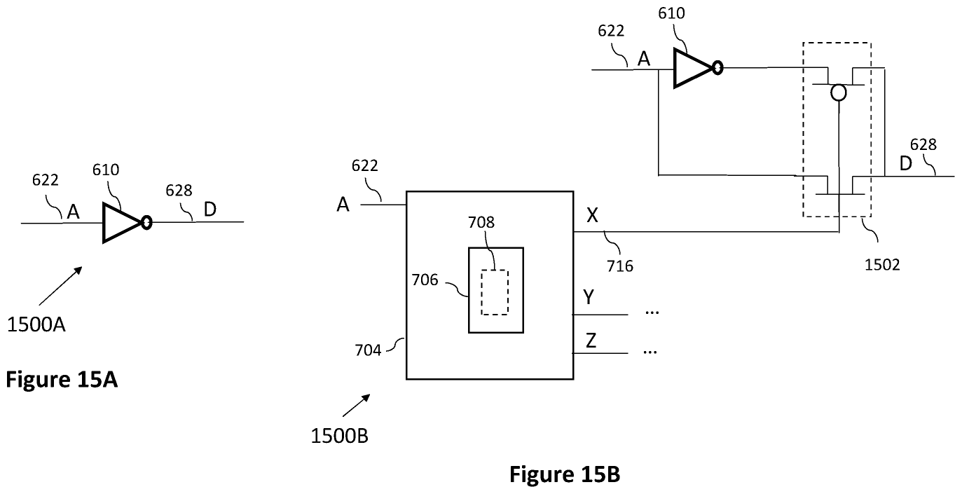

In some embodiments, a spare neural network cell may be added to a circuit in correspondence of an inverter without replacing the inverter with an XOR gate. For example, FIGS. 15A and 15B, illustrate a portion of an IC before and after the insertion of the adaptive NN cell 704 respectively. Common reference numerals and variables between Figures denote common features.

In FIG. 15B instead of replacing the inverter 610 with the XNOR gate 710, a transmission gate 1504 is used to control which signal (A or X) is coupled to D. The transmission gate 1504 is controlled by the output X of the digital NN circuit 406 and when the spare NN is inactive X is set to “0”.

Replacing the inverter 610 with XNOR gate 710 may be convenient in embodiments where additional functionality to SET & RESET the node D is required, whereas the implementation of FIG. 15B may be more convenient in circuits with critical timing constraints.

Many other implementations could be used to fit the timing and power requirements of the digital circuits of the present disclosure.

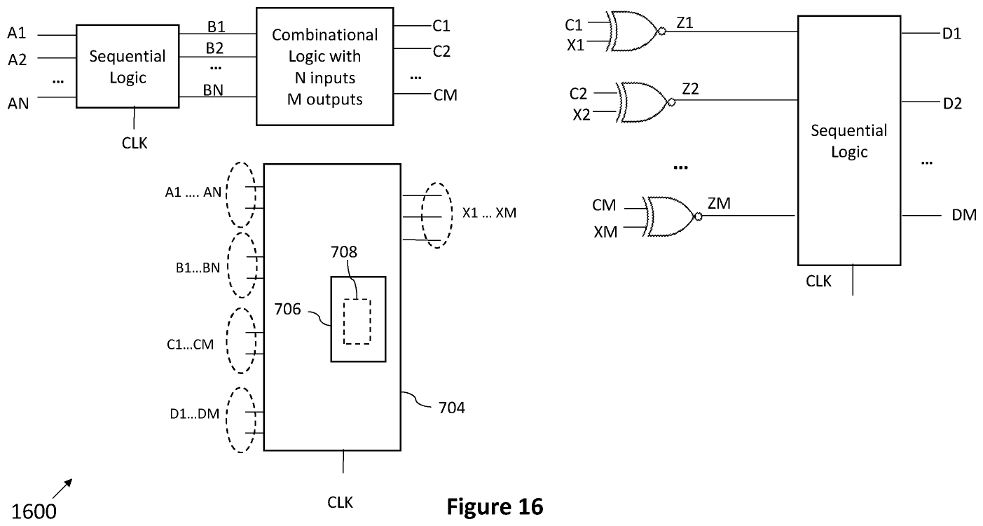

FIG. 16 is a schematic diagram of a configurable integrated circuit 1600 according to a fifth embodiment of the circuit 300 of FIG. 3. Common reference numerals and variables between Figures denote common features.

In this embodiment the adaptive neural network cell 704 receives in input both signals at nodes which are upstream (A1 through AN, B1 through BN, C1 through CM) from the adaptive NN cell and signals which are downstream (D1 through DM) from the adaptive NN cell in the circuit.

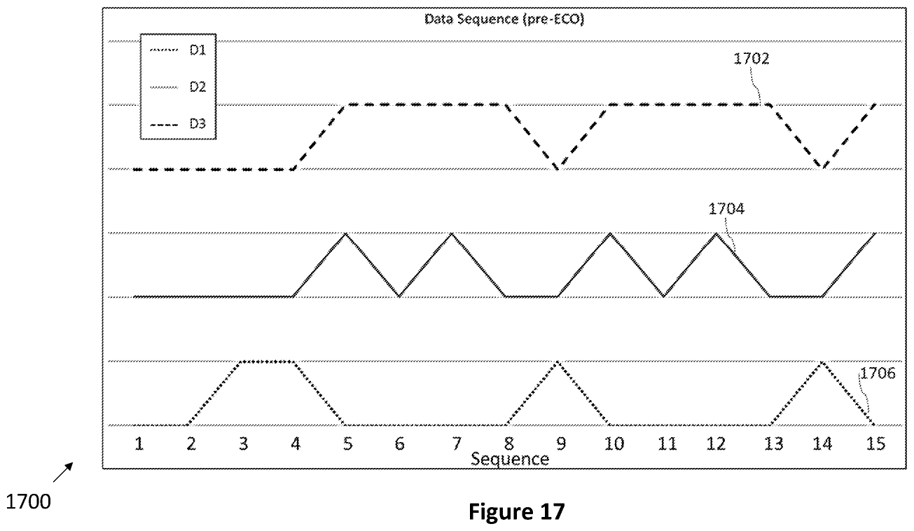

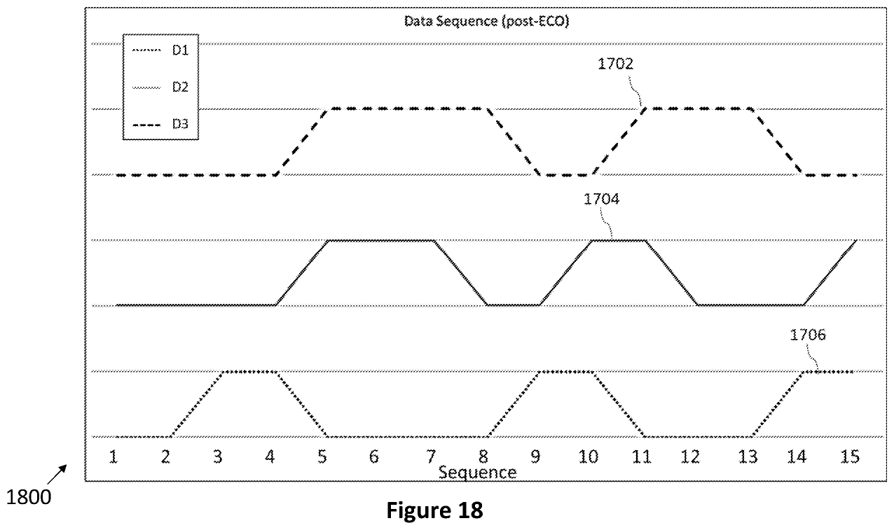

FIG. 17 and FIG. 18 are graphs illustrating a simulation in which the neural network 704 of FIG. 16 is configured to correct glitching. The graphs 1700 and 1800 illustrates the temporal evolution of the signals D1 through DM of circuit 1600 where N=4 and M=3. The graph 1700 of FIG. 17 illustrate the signals D1, D2 and D3 in a scenario in which the adaptive neural network cell is in the passive state (i.e. no correction or change has been applied in response to an ECO.

The graph 1800 of FIG. 18 illustrates the signals D1, D2 and D3 after the NN has been trained and the adaptive neural network cell 704 has been configured with weights and biases to achieve deglitching.

The resulting weights and biases were as follows:
A1+A2+A3>Bias, Weights {1,1,0}, Bias=1.5
A1+A3+A4>Bias, Weights {0,1,1}, Bias=1.5
A2+A3+A4>Bias, Weights {1,1,1}, Bias=0
B1+B2+B3>Bias, Weights {1,1,1}, Bias=1.5

The simulated output signals are shown in the table below:

| Sequence | 1 | 2 | 3 | 4 | 5 | 6 | 7 | 8 | 9 | 10 | 11 | 12 | 13 | 14 | 15 |
|---|---|---|---|---|---|---|---|---|---|---|---|---|---|---|---|
| X1 | 0 | 0 | 0 | 0 | 0 | 0 | 0 | 0 | 0 | 1 | 0 | 0 | 0 | 0 | 1 |
| X2 | 0 | 0 | 0 | 0 | 0 | 1 | 0 | 0 | 0 | 0 | 1 | 1 | 0 | 0 | 0 |
| X3 | 0 | 0 | 0 | 0 | 0 | 0 | 0 | 0 | 0 | 1 | 0 | 0 | 0 | 0 | 1 |

More complex integrated circuits may include further sequential and/or combination logic blocks and further signals may be input into the adaptive neural network cell(s).

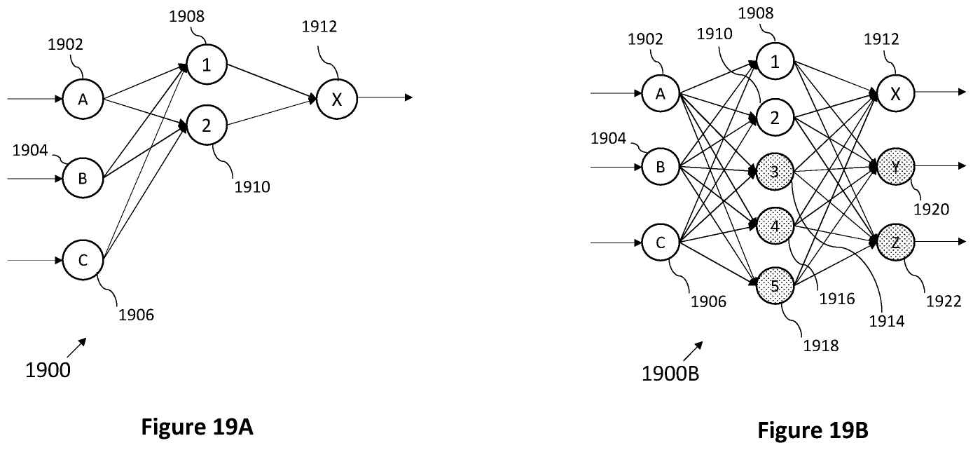

In some embodiments the baseline circuit layout 506 may already comprise some neural network circuits, for example for performing inferencing tasks. In this case, the adaptive neural network cell 704 may be implemented by adding redundant nodes to the pre-existing neural network circuits. In other words, the neural network 708 implemented by cell 704 is an extension of a pre-existing NN which is part of the baseline circuit layout 506 and configured to implement an inferencing task. This is illustrated in FIG. 19A and FIG. 19B.

FIG. 19A is a schematic diagram of a neural network topology 1900. The neural network 1900 comprises: an input layer with three input nodes 1902, 1904 and 1906; a hidden layer with two hidden nodes 1908, 1910; and an output layer with one output node 1912. The neural network 1900 may be configured for example to perform an inferencing task.

FIG. 19B is a schematic diagram of a modified neural network 1900′ comprising some redundant nodes. The modified neural network 1900′ comprises the same nodes as the neural network 1900. In addition, the neural network 1900′ further comprises three redundant hidden nodes 1914, 1916 and 1918 and two redundant output nodes 1920 and 1922. The inputs A, B, C, the hidden nodes 1908 and 1910 and the output 1012 form a first neural network configured to implement the same functionality as neural network 1900. The input A, B, C, the hidden nodes 1914, 1916 and 1918 and the output 1920 and 1922 form an adaptive neural network cell which is configurable for achieving a target circuit modification.

With reference to FIG. 5, the baseline circuit layout 506 may comprise a digital neural network circuit for implementing the neural network 1900. The baseline layout may then be modified at step 508 to add an adaptive NN cell comprising the redundant nodes 1914, 1916 and 1918.

Prior to an ECO order the weights of the redundant nodes are all zeros, that is, the redundant nodes are inactive, or passive. Following an ECO, the weights of the redundant nodes can be configured such that the adaptive NN cell achieves the target circuit modification. After an ECO, all cross-weights between the redundant hidden and output nodes and the hidden and output nodes of the original neural network 1900 (e.g. the weight for the connection between hidden node 3 and output node X, or the weight for the connection between hidden node 2 and output node Y) are set to zero, so that the two portions of the neural network 1900′ can be used independently.

In some embodiments, combining the adaptive NN cell(s) with NN circuits which are pre-existing in a baseline circuit layout allow digital design modifications (ECO) that might be relevant for the input/output functions of the pre-existing NN.

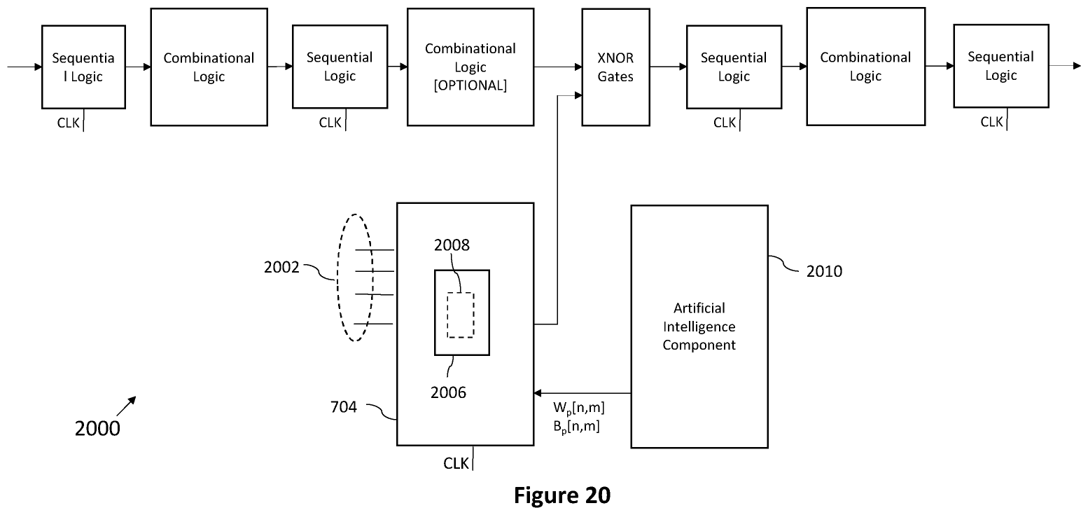

FIG. 20 is a schematic diagram of a configurable integrated circuit 2000 according to a sixth embodiment of the circuit 300 of FIG. 3.

The circuit 2000 comprises an adaptive NN cell 2004 comprising a digital NN circuit 2006 configured to implement a multi-clock deterministic neural network 2008. The adaptive NN cell 2004 is configured to implement dynamic optimization of the weights Wp[n,m] of the NN 2008. The inputs 2002 of the adaptive neural network cell 704 are selected such that they allow maximum functional coverage based on the available space, routing and timing constraint.

The adaptive NN cell 2000 is configured to communicate with an artificial intelligence component 2010, which in turn is configured to dynamically compute the set of weights values which allow to achieve the target circuit modification. In some embodiments, the AI component 2010 comprises a first, local AI component and a second, remote AI component coupled to the first AI component. For example, the remote AI component may be a cloud server-based AI component.

Increasing the depth of the spare NN cells(s), as well as the weights and bias precision, increases the available logic modifications that can be implemented by the spare NN cell(s). This however will require more layout space and increasing timing constraints.

In some embodiments, the methods of the present disclosure comprise optimizing the number, configuration and location of the adaptive NN cells in order to determine which adaptive NN cells configuration enables the widest range of circuit modifications whilst complying with the space and timing constraints of the IC. The depth and precision of each spare neural network cell of may be expanded based on the available timing margin of the paths where the adaptive NN cell is placed.

The dimensions and position of each spare NN cell can be decided during the design phase based on various factors, such as route congestion, critical timing constraints, validation coverage analysis from functional verification of the RTL model.

In some embodiments the methods of the present disclosure further comprise increasing the size of the digital design or reducing the clock frequency in order to meet the timing and space requirements that can accommodate more complex adaptive NN cells and therefore enable wider changes and/or corrections following an ECO.

Reducing the clock frequency also provides a debug opportunity in that substantial ECO can be tested with the same silicon.

In some embodiment adaptive NN cells can be combined with neural network circuits configured to determine power gating functionality for various blocks within the digital IC design.

Adaptive NN cells may also be used in combination with prior art spare logic gates in order to minimize the metal mask changes required for ECO modifications.

All of the above embodiments can be used for extending the functionality of a digital design and allow run time programmability.

ECO-ICs according to the present disclosure allow to extend the circuit design process to post silicon manufacturing of the IC without the overhead (or with minimal overhead) for programmability in terms of silicon area, timing constraint, or power consumption.

The adaptive neural network cells of the present disclosure may also be coupled to system level inputs and outputs for potential future use cases that are not defined at the time of physical layout.

In some embodiments, the method 400 of the present disclosure comprises exploring all possible combinations of weights and biases of each binarized NN implemented by the adaptive NN cells which are to be added to the IC; optimizing the topology of each adaptive NN cell based on the critical timing constraints, power and data path combinations which can be implemented by each weight and biases combination; and implementing said topology.

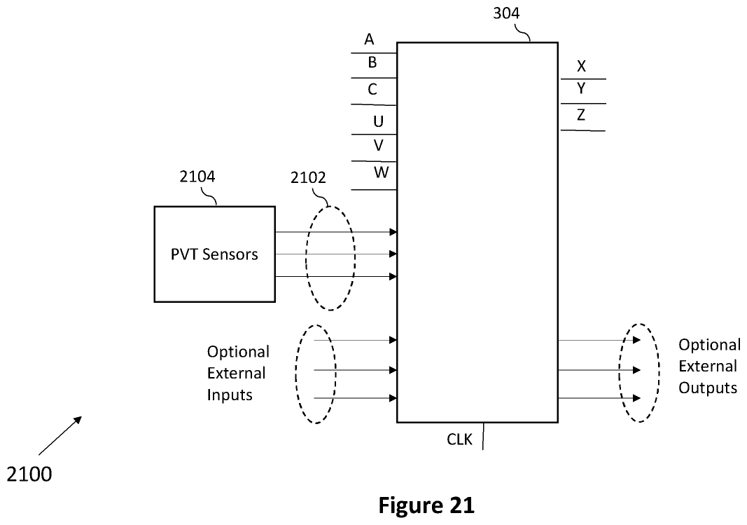

In some embodiments, the adaptive neural network cells of the present disclosure may be configured to receive in input additional system level signals. For example, they may receive in input data from PVT sensors (Process-Voltage-Temperature monitors) to determine ECO modifications that might be required only at certain operating conditions, as illustrated in FIG. 21.

FIG. 21 is a schematic diagram of a configurable integrated circuit 2100 according to a seventh embodiment of the circuit 300 of FIG. 3 in which the adaptive neural network cell 304 receives in input a plurality of signals 2102 from a PVT sensor 2104. Common reference numerals and variables between Figures denote common features.

In some embodiments wherein the adaptive neural network cell 304 is configured to receive in input system level signals, the adaptive neural network cell may enable the implementation of adaptive circuit functionalities based for example on the outcome of a self-calibration process (adaptive auto calibration) or on real-time system state parameters.

Digital Design Place & Route is a process which involves optimization of placement of library cells (logic gates, flip-flops, etc.) and macros (optimized and connected group of library cells into a group, memory, registers, interfaces, and specialized mixed signal function blocks such as PLL) with respect to each other. All the cells and macros are then connected in the so-called “Physical Design” in the manner as defined by the Logic Synthesis. The result is a layout that is typically optimized for size and timing constraints of the IC. In prior art circuits and methods, spare library cells are included in areas that are not fully populated to allow future modification of design with ECO. However, since spare cells require new connections in order to be activated in response to an ECO, that means new metal routing masks must be manufactured in order for the ECO modifications to be implemented. Instead, in the methods and systems according to the present disclosure, adaptive neural networks cells are included in available physical areas. The number of nodes and configurability of these adaptive NN cells can be maximized depending on the space available and timing constraints. These adaptive NN cells, are connected to various nodes in the digital design such that the additional digital functionality of the adaptive NN cells increases the testing and validation coverage of the digital design, where validation coverage refers to full scope of potential modifications of the IC functionality which are achievable with the adaptive NN cells. Methods such as state-graph can be used to find the maximum coverage achievable with a given set of adaptive NN cells.

Adaptive NN cells are never required for the IC to function as defined in the original circuit specification or layout, but they allow the IC to be modified to conform with any future ECO. Increasing the validation coverage increases the probability of finding a solution for any ECO that might be required.

Therefore, the methods and system of the present disclosure allow to re-design a circuit in response to an ECO without requiring re-synthesis and new routing mask layers to be produced. The methods and systems of the present disclosure provide fully connected but unused (spare) digital neural network cells that can be used to implement the new functionality as required by an ECO by simply changing the weights and biases of the neural network.

The methods and systems of the present disclosure can be further extended to cover integrated circuit design performed by very high dimensional optimization-capable systems such as artificial intelligence systems.

A logical extension of the design systems and methods disclosed above for ECO-ICs is to combine multiple clock logic block(s) with a deterministic NN, which expands the possible values of a given combinational logic block(s). Design of such a circuit is better suited to be performed by AI which can handle the exponential increase in possible logical function outcomes with changing weights and biases of multiple clocks.

The circuits and methods of the present disclosure may be used for realizing IC with embedded intelligence in closed-loop systems, such as in the embodiment illustrated in FIG. 20. As an example application, the circuit 2000 may be utilized in the circuit controls of patent application U.S. 63/066,419 which is hereby incorporated by reference. The neural network digital circuit 706 can be utilized to generate adaptive system response that can be configured after tape-out. Such adaptive neural network digital circuit can be complementary to the baseline control circuit where the controller is fully functional without the use of the adaptive neural network cell.

The above use case above can also be viewed as a new class of integrated circuits where the design changes and functional coverage is included as an interface to cloud based artificial intelligence systems. In this case ECO-IC would be designed with maximum functional coverage for ECO relative to the available physical space, timing and power constraints as determined by a cloud-based AI component and using a digital ECO-IC model separately from any software programmability interface such as device drivers and software stacks. Currently datasheets are provided in human readable format. Similarly, device drivers are provided in a format that allows software programmers to understand the structure and add/modify code for interfacing to the lower level device functions. If we remove this constraint and provide the available digital logic and the embedded spare NN for machine learning (including training etc) approach we do not need understandable structures for interfacing with the device including configuration and functionality. This will eliminate the possibility of any software programmer to write a code that interfaces directly with the device. But it will also eliminate the need for connectivity for software upgrades other than the outcome of training and the machine learning models used for system optimization.

This allows to reduce the overhead in silicon interface as well as communication for virtual system optimization that can generate the corresponding hardware (silicon) configuration directly without translation in software. The model of ECO-IC would be used within a virtual system (such as a digital twin) to obtain specific configuration parameters that provides the desired function within the virtual system and the configuration parameters would be set and determine the corresponding Engineering Change Order that determines silicon functionality.

Advanced semiconductor process nodes have reduced the dimension of CMOS transistors such that millions of transistors fit in a very small area of silicon allowing very complex operations to be implemented within mixed signal analog/digital design. The digital block within mixed signal circuits is typically referred to as custom digital design and flexibility of the design is explored within the limits of given constraints, with configurations and redundant functionality implemented within silicon area, design time, power and timing constraints. Applying ECO in these devices is very common and it is an indication of design process undertaken at the limits of these constraints. These custom digital designs are also supported by device drivers (software controlled hardware) and general purpose microcontrollers and microprocessors with an architecture designed to run based on the software code.

A further recent trends in custom digital designs is to complement digital design with inference accelerators (such as neural network-based inference accelerator) that provide real-time classification and higher order logic functionality (decision making). Due to various constraints typical implementation of these inference accelerators required the training of these neural networks to be performed on powerful servers and with extensive (cloud-based) data for determining the appropriate weights and biases. These weights and biases are then used in low power inference accelerator hardware at the edge or within the same silicon as the custom digital design. These inference accelerators are typically accompanied by custom digital design that handles configuration and interface functions as required.

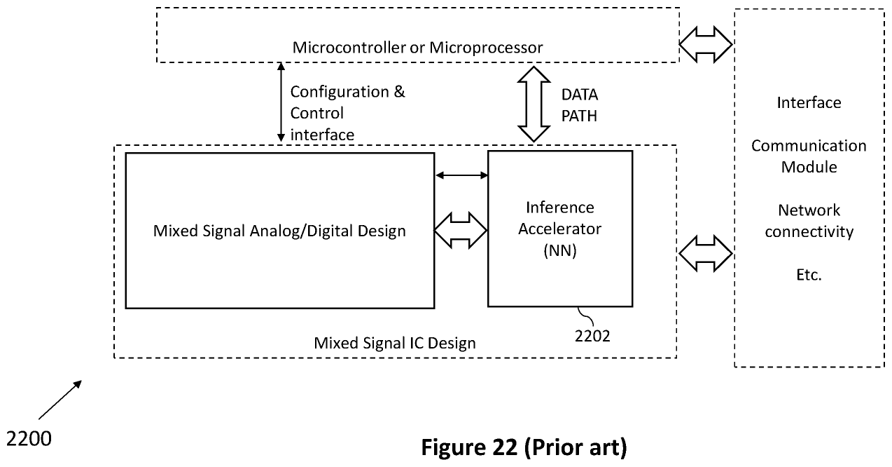

FIGS. 22, 23 and 24 illustrate the above concept.

FIG. 22 is a schematic diagram of a prior art digital circuit 2200 for use in a mixed-signal (analog/digital) circuit. The circuit 2200 comprises an inference accelerator 2202 for classification, regression, or other types of edge computing. The programmability is typically achieved with a microcontroller or microprocessor which executes embedded software code. System architecture includes interface to external systems for data transmission and embedded software updates. Custom digital design is completed at silicon manufacturing including the anticipated configurations for changing functional logic.

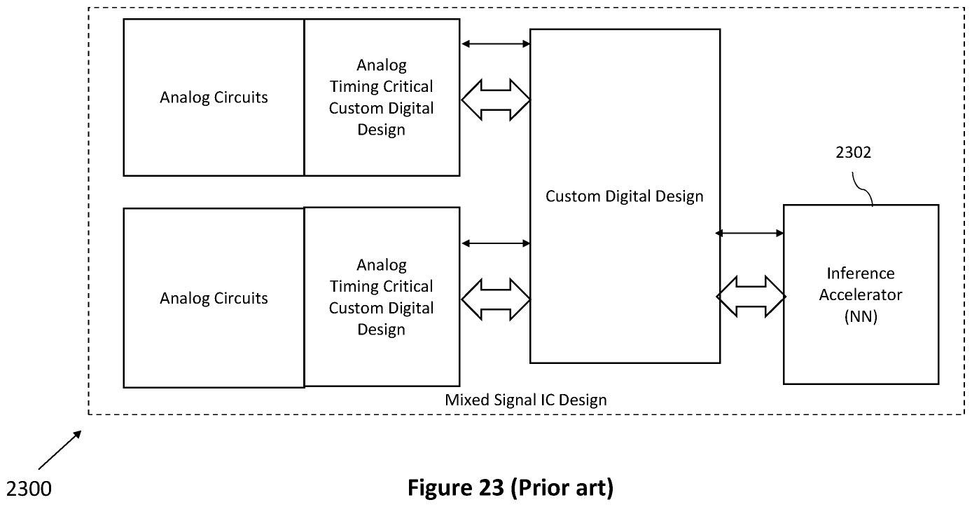

FIG. 23 is a schematic diagram of a prior art digital circuit 2300 which is configured to provide timing critical signals for controlling the analog portion of a mixed-signal circuit. The circuit 2300 comprises an inference accelerator 2302 that typically uses weights determined by a training step performed externally with bigger data sets.

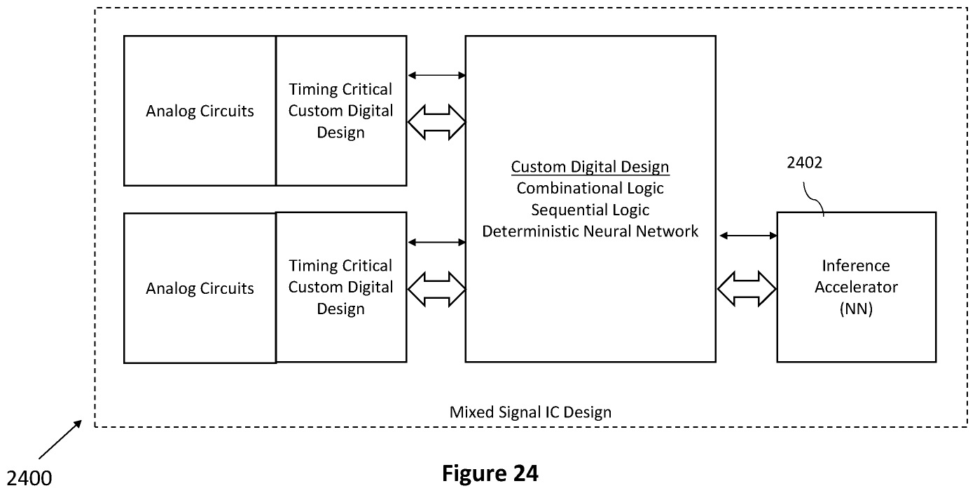

FIG. 24 is a schematic diagram of a digital circuit which combines deterministic neural networks with combinational and sequential logic blocks according to the present disclosure. The circuit 2400 may comprise an inference accelerator 2402 analogous to the inference accelerator 2202 and 2302 of FIGS. 22 and 23 respectively.

A skilled person appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A reconfigurable integrated circuit comprising:
a plurality of active cells; and
an adaptive neural network cell coupled to one or more active cells, the adaptive neural network cell comprising a digital neural network circuit configured to implement a first neural network having a plurality of weights and biases;
wherein for specific weights and biases and specific neural network inputs, the first neural network provides specific neural network outputs; and
wherein the adaptive neural network cell is configurable with a set of target weights to achieve a target circuit modification.

2. The reconfigurable integrated circuit as claimed in claim 1, wherein:
the adaptive neural network cell has an active state and a passive state; and
in the active state the adaptive neural network cell provides target outputs for the target circuit modification.

3. The reconfigurable integrated circuit as claimed in claim 1, wherein in the passive state the outputs of the adaptive neural network cell are all set to a logic zero or all set to a predefined set of outputs that do not achieve the target circuit modification.

4. The reconfigurable integrated circuit as claimed in claim 1, wherein:
the first neural network has one or more hidden nodes; and
the digital neural network circuit comprises a first circuit portion to provide a plurality of hidden node values and a second circuit portion to provide one or more output values.

5. The reconfigurable integrated circuit as claimed in claim 4, wherein the first circuit portion comprises:
a first set of stage 1 circuits associated with a corresponding input signal and a corresponding hidden node, wherein each stage 1 circuit is adapted to:
receive the corresponding input signal and one or more weight signals encoding the weight of the corresponding input signal and the corresponding hidden node; and
provide one or more output signals associated with a product function for determining the corresponding hidden node; and
a second set of stage 2 circuits, wherein each stage 2 circuit is associated with a corresponding hidden node, wherein each stage-2 circuit is adapted to receive one or more outputs signals from each stage 1 circuit associated with the corresponding hidden node and to provide a value of the corresponding hidden node.

6. The reconfigurable integrated circuit as claimed in claim 3, wherein the second circuit portion is analogous to the first portion.

7. The reconfigurable integrated circuit as claimed in claim 1, wherein the first neural network is a deterministic neural network.

8. The reconfigurable integrated circuit as claimed in claim 1, wherein one or more of the inputs, the outputs, the weights, and the biases of the first neural network are quantized.

9. The reconfigurable integrated circuit as claimed in claim 8, wherein one or more of the outputs, the inputs, the weights, and the biases of the first neural network are binarized.

10. The reconfigurable integrated circuit as claimed in claim 1, wherein the plurality of active cells comprises one or more active logic cells.

11. The reconfigurable integrated circuit as claimed in claim 10, wherein the plurality of active cells comprises at least one of: a combinatorial logic cell and a sequential logic cell.

12. The reconfigurable integrated circuit as claimed in claim 1, wherein the adaptive neural network cell is configurable to implement a logic cell.

13. The reconfigurable integrated circuit as claimed in claim 1, wherein one of the active cells comprises a digital circuit implementing a second neural network and the first neural network is an extension of the second neural network.

14. The reconfigurable integrated circuit as claimed in claim 1, wherein the adaptive neural network cell is further configurable with a set of target biases to achieve the target circuit modification.

15. A method of reconfiguring an integrated circuit, the method comprising:
providing an integrated circuit comprising a plurality of active cells and an adaptive neural network cell coupled to one or more active cells, the adaptive neural network cell comprising a digital neural network circuit configured to implement a first neural network having a plurality of weights and biases;
wherein for specific weights and biases and specific neural network inputs, the first neural network provides specific neural network outputs;
identifying a target circuit modification to be achieved via the adaptive neural network cell;
determining a set of weights associated with target outputs for the target circuit modification; and
configuring the adaptive neural network cell with the set of weights to achieve the target circuit modification.

16. The method of reconfiguring an integrated circuit as claimed in claim 15, wherein the adaptive neural network cell has an active state and a passive state, wherein in the active state the adaptive neural network cell provides target outputs for the target circuit modification; the method further comprising
prior to a target circuit modification being identified, performing a step selected from the following:
setting all the neural network outputs to zero to achieve the passive state; and
determining a set of weights associated with the passive state and configuring the adaptive neural network cell with the set of weights to achieve the passive state.

17. The method as claimed in claim 15, wherein determining the set of weights to achieve the target circuit modification comprises training the first neural network via a processor.

18. The method of claim 15, wherein the plurality of active cells comprises an inverter between a first logic block and a second logic block, the method further comprising:
replacing the inverter with an XNOR gate or AOI gate; and
coupling the adaptive neural network cell between the first logic block and the XNOR gate or the AOI gate.

19. The method of claim 15, wherein the method further comprises:
determining a set of biases associated with target outputs for the target circuit modification; and
configuring the adaptive neural network cell with the set of biases to achieve the target circuit modification.
